(19) United States
(12) Patent Application Publication
(10) Pub. No.: US 2013/0100518 A1
(43) Pub. Date: Apr. 25, 2013

(54) TUNING MOVABLE LAYER STIFFNESS WITH FEATURES IN THE MOVABLE LAYER

(71) Applicants: Chandra Shekar Reddy Tupelly, San Ramon, CA (US); Yi Tao, San Jose, CA (US); Kostadin Dimitrov Djordjev, San Jose, CA (US); Lior Kogut, Haifa (IL); Brian William Arbuckle, Danville, CA (US); Brian James Gally, Los Gatos, CA (US); Ming-Hau Tung, San Francisco, CA (US)

(72) Inventors: Chandra Shekar Reddy Tupelly, San Ramon, CA (US); Yi Tao, San Jose, CA (US); Kostadin Dimitrov Djordjev, San Jose, CA (US); Lior Kogut, Haifa (IL); Brian William Arbuckle, Danville, CA (US); Brian James Gally, Los Gatos, CA (US); Ming-Hau Tung, San Francisco, CA (US)

(73) Assignee: QUALCOMM MEMS TECHNOLOGIES, INC., San Diego, CA (US)

(21) Appl. No.: 13/403,640

(22) Filed: Feb. 23, 2012

Related U.S. Application Data
(60) Provisional application No. 61/549,665, filed on Oct. 20, 2011.

(51) Int. Cl. G02B 26/00; H01L 21/02; H02N 1/00

(52) U.S. Cl. 359/290; 310/300; 438/50; 257/E21.002

(57) ABSTRACT

This disclosure provides systems, methods and apparatus for an electromechanical systems device. In one aspect, an electromechanical systems device may include a substrate and a movable layer positioned apart from the substrate. The movable layer and the substrate may define a cavity. The movable layer may be movable to increase the size of the cavity or to decrease the size of the cavity. The movable layer also may include a first anchor point attaching the movable layer to the substrate and a first feature associated with the first anchor point. The first feature may include a protrusion of the movable layer into or out from the cavity.

### CROSS-REFERENCE TO RELATED APPLICATIONS

This disclosure claims priority to U.S. Provisional Patent Application No. 61/549,665, filed Oct. 20, 2011, entitled “TUNING MOVABLE LAYER STIFFNESS BY CREATING FEATURES IN THE MOVABLE LAYER,” and assigned to the assignee hereof. The disclosure of the prior application is considered part of, and is incorporated by reference in, this disclosure.

### TECHNICAL FIELD

This disclosure relates generally to electromechanical systems (EMS) devices and more particularly to movable layers in EMS devices.

### DESCRIPTION OF THE RELATED TECHNOLOGY

Electromechanical systems (EMS) include devices having electrical and mechanical elements, actuators, transducers, sensors, optical components (including mirrors) and electronics. Electromechanical systems can be manufactured at a variety of scales including, but not limited to, microscales and nanoscales. For example, microelectromechanical systems (MEMS) devices can include structures having sizes ranging from about a micron to hundreds of microns or more. Nanoelectromechanical systems (NEMS) devices can include structures having sizes smaller than a micron including, for example, sizes smaller than several hundred nanometers. Electromechanical elements may be created using deposition, etching, lithography, and/or other micromachining processes that etch away parts of substrates and/or deposited material layers, or that add layers to form electrical and electromechanical devices.

One type of EMS device is called an interferometric modulator (IMOD). As used herein, the term interferometric modulator or interferometric light modulator refers to a device that selectively absorbs and/or reflects light using the principles of optical interference. In some implementations, an interferometric modulator may include a pair of conductive plates, one or both of which may be transparent and/or reflective, wholly or in part, and capable of relative motion upon application of an appropriate electrical signal. In an implementation, one plate may include a stationary layer deposited on a substrate and the other plate may include a reflective membrane separated from the stationary layer by an air gap. The position of one plate in relation to another can change the optical interference of light incident on the interferometric modulator. Interferometric modulator devices have a wide range of applications, and are anticipated to be used in improving existing products and creating new products, especially those with display capabilities.

An EMS device may include one or more movable layers, such as a reflective membrane or other deformable layer. A movable layer can be characterized by a stiffness, which may depend in part on the thickness of and the residual stresses in the movable layer.

### SUMMARY

The systems, methods and devices of the disclosure each have several innovative aspects, no single one of which is solely responsible for the desirable attributes disclosed herein.

One innovative aspect of the subject matter described in this disclosure can be implemented in a device including a substrate and a movable layer positioned apart from the substrate. The movable layer and the substrate may define a cavity. The movable layer may be movable to increase the size of the cavity or to decrease the size of the cavity. The movable layer may include a first anchor point attaching the movable layer to the substrate. The movable layer also may include a first feature associated with the first anchor point. The first feature may include a protrusion of the movable layer into or out from the cavity.

In some implementations, the first feature may extend substantially radially from the first anchor point. In such implementations, the first feature may increase a force that causes the movable layer to move. In some implementations, the first feature substantially may form an arc associated with the first anchor point. In such implementations, the first feature may decrease a force that causes the movable layer to move.

Another innovative aspect of the subject matter described in this disclosure can be implemented in an electromechanical systems reflective display device including a substrate and a movable layer positioned apart from the substrate. The movable layer and the substrate may define a cavity. The movable layer may be movable into or out from the cavity. The substrate and the movable layer may form an optically active region configured to transmit and reflect light and an optically inactive region configured to absorb light. The movable layer may include a first feature in the optically inactive region of the movable layer. The first feature may include a protrusion of the movable layer into or out from the cavity.

In some implementations, the first feature of the electromechanical systems reflective display device may extend substantially radially from a first anchor point within the optically inactive region, with the first anchor point attaching the movable layer to the substrate. In some implementations, the first feature of the electromechanical systems reflective display device substantially may form an arc associated with a first anchor point within the optically inactive region, with the first anchor point attaching the movable layer to the substrate.

Another innovative aspect of the subject matter described in this disclosure can be implemented in a device including a substrate and a movable layer positioned apart from the substrate. The movable layer and the substrate may define a cavity. The movable layer may be movable to increase the size of the cavity or to decrease the size of the cavity. The movable layer may include means for increasing or decreasing a force that causes the movable layer to move. The device further may include means for attaching the movable layer to the substrate.

In some implementations, the means for increasing or decreasing the force that causes the movable layer to move includes a first feature associated with the means for attaching the movable layer to the substrate. In some implementations, the means for attaching the movable layer to the substrate includes a first anchor point.

Another innovative aspect of the subject matter described in this disclosure can be implemented a method including forming a sacrificial layer over a substrate. The sacrificial layer may include a molding feature. A movable layer may be formed over the sacrificial layer. The movable layer may include a first anchor point attaching the movable layer to the substrate. The movable layer also may include a first feature formed by the molding feature in the sacrificial layer. The first feature may be associated with the first anchor point. The sacrificial layer may be removed to form a cavity in between the movable layer and the substrate. The first feature may include a protrusion of the movable layer into or out from the cavity. In some implementations, the sacrificial layer may include at least one of amorphous silicon and molybdenum.

Details of one or more implementations of the subject matter described in this specification are set forth in the accompanying drawings and the description below. Although the examples provided in this disclosure are primarily described in terms of electromechanical systems (EMS) and microelectromechanical systems (MEMS)-based displays, the concepts provided herein may apply to other types of displays, such as liquid crystal displays, organic light-emitting diode (“OLED”) displays and field emission displays. Other features, aspects, and advantages will become apparent from the description, the drawings and the claims. Note that the relative dimensions of the following figures may not be drawn to scale.

### BRIEF DESCRIPTION OF THE DRAWINGS

FIG. 1 shows an example of an isometric view depicting two adjacent pixels in a series of pixels of an interferometric modulator (IMOD) display device.

FIG. 2 shows an example of a system block diagram illustrating an electronic device incorporating a 3×3 interferometric modulator display.

FIG. 3 shows an example of a diagram illustrating movable reflective layer position versus applied voltage for the interferometric modulator of FIG. 1.

FIG. 4 shows an example of a table illustrating various states of an interferometric modulator when various common and segment voltages are applied.

FIG. 5A shows an example of a diagram illustrating a frame of display data in the 3×3 interferometric modulator display of FIG. 2.

FIG. 5B shows an example of a timing diagram for common and segment signals that may be used to write the frame of display data illustrated in FIG. 5A.

FIG. 6A shows an example of a partial cross-section of the interferometric modulator display of FIG. 1.

FIGS. 6B-6E show examples of cross-sections of varying implementations of interferometric modulators.

FIG. 7 shows an example of a flow diagram illustrating a manufacturing process for an interferometric modulator.

FIGS. 8A-8E show examples of cross-sectional schematic illustrations of various stages in a method of making an interferometric modulator.

FIGS. 9A and 9B show examples of schematic illustrations of an electromechanical systems (EMS) device.

FIGS. 10A-10D show examples of schematic illustrations of EMS devices including a movable layer having a feature associated with each anchor point of the movable layer.

FIGS. 11A-11E show examples of schematic illustrations of EMS devices including a movable layer having two features associated with each anchor point of the movable layer.

FIGS. 12A and 12B show examples of top-down schematic illustrations of an anchor point of a movable layer and features associated with the anchor point.

FIGS. 13 and 14 show examples of flow diagrams illustrating manufacturing processes for forming a movable layer of an EMS device.

FIGS. 15A-15C show examples of cross-sectional schematic illustrations of an EMS device in various stages of the manufacturing process shown in FIG. 14.

FIGS. 16A and 16B show examples of system block diagrams illustrating a display device that includes a plurality of interferometric modulators.

Like reference numbers and designations in the various drawings indicate like elements.

The following description is directed to certain implementations for the purposes of describing the innovative aspects of this disclosure. However, a person having ordinary skill in the art will readily recognize that the teachings herein can be applied in a multitude of different ways. The described implementations may be implemented in any device or system that can be configured to display an image, whether in motion (e.g., video) or stationary (e.g., still image), and whether textual, graphical or pictorial. More particularly, it is contemplated that the described implementations may be included in or associated with a variety of electronic devices such as, but not limited to: mobile telephones, multimedia Internet enabled cellular telephones, mobile television receivers, wireless devices, smartphones, Bluetooth® devices, personal data assistants (PDAs), wireless electronic mail receivers, hand-held or portable computers, netbooks, notebooks, smartbooks, tablets, printers, copiers, scanners, facsimile devices, GPS receivers/navigators, cameras, MP3 players, camcorders, game consoles, wrist watches, clocks, calculators, television monitors, flat panel displays, electronic reading devices (i.e., e-readers), computer monitors, auto displays (including odometer and speedometer displays, etc.), cockpit controls and/or displays, camera view displays (such as the display of a rear view camera in a vehicle), electronic photographs, electronic billboards or signs, projectors, architectural structures, microwaves, refrigerators, stereo systems, cassette recorders or players, DVD players, CD players, VCRs, radios, portable memory chips, washers, dryers, washer/dryers, parking meters, packaging (such as in electromechanical systems (EMS), microelectromechanical systems (MEMS) and non-MEMS applications), aesthetic structures (e.g., display of images on a piece of jewelry) and a variety of EMS devices. The teachings herein also can be used in non-display applications such as, but not limited to, electronic switching devices, radio frequency filters, sensors, accelerometers, gyroscopes, motion-sensing devices, magnetometers, inertial components for consumer electronics, parts of consumer electronics products, varactors, liquid crystal devices, electrophoretic devices, drive schemes, manufacturing processes and electronic test equipment. Thus, the teachings are not intended to be limited to the implementations depicted solely in the Figures, but instead have wide applicability as will be readily apparent to one having ordinary skill in the art.

Some implementations described herein relate to features in a movable layer of an EMS device. The movable layer may be relatively stiff or may be relatively compliant, depending in part on the thickness of the movable layer and residual stresses that may be present in the movable layer. The stiffness of the movable layer also may be affected by features formed in the movable layer.

In some implementations described herein, an EMS device may include a substrate and a movable layer positioned apart from the substrate. The movable layer and the substrate may define a cavity. The movable layer may be movable to increase the size of the cavity or to decrease the size of the cavity. The movable layer may include a first anchor point attaching the movable layer to the substrate. The movable layer also may include a first feature associated with the first anchor point. The first feature may include a protrusion of the movable layer into or out from the cavity.

Particular implementations of the subject matter described in this disclosure can be implemented to realize one or more of the following potential advantages. In some EMS devices, the thickness of the movable layer may be defined by the EMS device design and the fabrication process capabilities. The residual stresses in the movable layer may be determined by the processes used to fabricate the movable layer and/or other EMS device components. Features formed in the movable layer of an EMS device may provide another way to affect the stiffness of the movable layer. Tuning the stiffness of a movable layer of an EMS device may be increasingly important as the sizes of EMS devices decrease so that more EMS devices may be included in a given area or volume. In some implementations, forming features in the movable layer of an EMS device may be performed without using additional masks when preceding layers formed for the EMS device are used to form the features.

For example, features in the movable layers of an EMS display device may be used to tune the stiffness of the movable layers for individual pixels of the EMS display device. Tuning the stiffness of a movable layer for a pixel may allow the pixel to operate at a desired voltage. Tuning the stiffness of a movable layer for a pixel may be increasingly important as the sizes of individual pixels of an EMS display device decrease for increased resolution displays, for example.

An example of a suitable EMS or MEMS device, to which the described implementations may apply, is a reflective display device. Reflective display devices can incorporate interferometric modulators (IMODs) to selectively absorb and/or reflect light incident thereon using principles of optical interference. IMODs can include an absorber, a reflector that is movable with respect to the absorber, and an optical resonant cavity defined between the absorber and the reflector. The reflector can be moved to two or more different positions, which can change the size of the optical resonant cavity and thereby affect the reflectance of the interferometric modulator. The reflectance spectrums of IMODs can create fairly broad spectral bands which can be shifted across the visible wavelengths to generate different colors. The position of the spectral band can be adjusted by changing the thickness of the optical resonant cavity, i.e., by changing the position of the reflector.

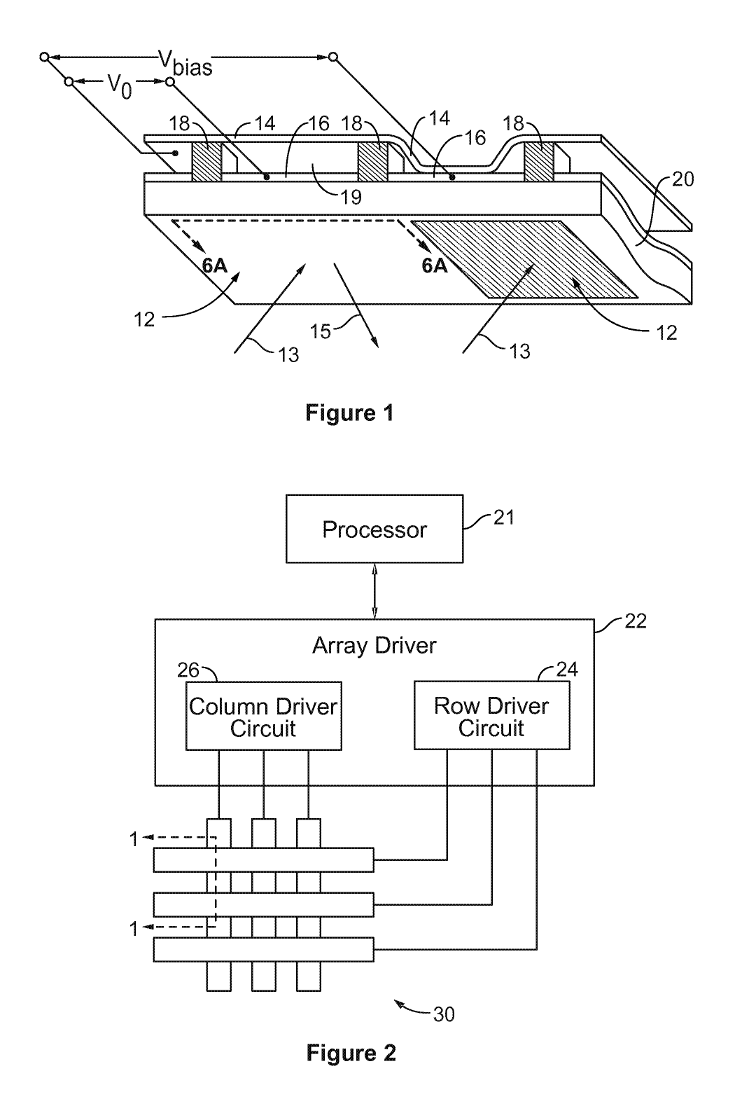

FIG. 1 shows an example of an isometric view depicting two adjacent pixels in a series of pixels of an interferometric modulator (IMOD) display device. The IMOD display device includes one or more interferometric MEMS display elements. In these devices, the pixels of the MEMS display elements can be in either a bright or dark state. In the bright (“relaxed,” “open” or “on”) state, the display element reflects a large portion of incident visible light, e.g., to a user. Conversely, in the dark (“actuated,” “closed” or “off”) state, the display element reflects little incident visible light. In some implementations, the light reflectance properties of the on and off states may be reversed. MEMS pixels can be configured to reflect predominantly at particular wavelengths allowing for a color display in addition to black and white.

The IMOD display device can include a row/column array of IMODs. Each IMOD can include a pair of reflective layers, i.e., a movable reflective layer and a fixed partially reflective layer, positioned at a variable and controllable distance from each other to form an air gap (also referred to as an optical gap or cavity). The movable reflective layer may be moved between at least two positions. In a first position, i.e., a relaxed position, the movable reflective layer can be positioned at a relatively large distance from the fixed partially reflective layer. In a second position, i.e., an actuated position, the movable reflective layer can be positioned more closely to the partially reflective layer. Incident light that reflects from the two layers can interfere constructively or destructively depending on the position of the movable reflective layer, producing either an overall reflective or non-reflective state for each pixel. In some implementations, the IMOD may be in a reflective state when unactuated, reflecting light within the visible spectrum, and may be in a dark state when unactuated, reflecting light outside of the visible range (e.g., infrared light). In some other implementations, however, an IMOD may be in a dark state when unactuated, and in a reflective state when actuated. In some implementations, the introduction of an applied voltage can drive the pixels to change states. In some other implementations, an applied charge can drive the pixels to change states.

The depicted portion of the pixel array in FIG. 1 includes two adjacent interferometric modulators 12. In the IMOD 12 on the left (as illustrated), a movable reflective layer 14 is illustrated in a relaxed position at a predetermined distance from an optical stack 16, which includes a partially reflective layer. The voltage V₀ applied across the IMOD 12 on the left is insufficient to cause actuation of the movable reflective layer 14. In the IMOD 12 on the right, the movable reflective layer 14 is illustrated in an actuated position near or adjacent the optical stack 16. The voltage V_{bias} applied across the IMOD 12 on the right is sufficient to maintain the movable reflective layer 14 in the actuated position.

In FIG. 1, the reflective properties of pixels 12 are generally illustrated with arrows 13 indicating light incident upon the pixels 12, and light 15 reflecting from the IMOD 12 on the left. Although not illustrated in detail, it will be understood by one having ordinary skill in the art that most of the light 13 incident upon the pixels 12 will be transmitted through the transparent substrate 20, toward the optical stack 16. A portion of the light incident upon the optical stack 16 will be transmitted through the partially reflective layer of the optical stack 16, and a portion will be reflected back through the transparent substrate 20. The portion of light 13 that is transmitted through the optical stack 16 will be reflected at the movable reflective layer 14, back toward (and through) the transparent substrate 20. Interference (constructive or destructive) between the light reflected from the partially reflective layer of the optical stack 16 and the light reflected from the movable reflective layer 14 will determine the wavelength(s) of light 15 reflected from the IMOD 12.

The optical stack 16 can include a single layer or several layers. The layer(s) can include one or more of an electrode layer, a partially reflective and partially transmissive layer and a transparent dielectric layer. In some implementations, the optical stack 16 is electrically conductive, partially transparent and partially reflective, and may be fabricated, for example, by depositing one or more of the above layers onto a transparent substrate 20. The electrode layer can be formed from a variety of materials, such as various metals, for example indium tin oxide (ITO). The partially reflective layer can be formed from a variety of materials that are partially reflective, such as various metals, e.g., chromium (Cr), semiconductors, and dielectrics. The partially reflective layer can be formed of one or more layers of materials, and each of the layers can be formed of a single material or a combination of materials. In some implementations, the optical stack 16 can include a single semi-transparent thickness of metal or semiconductor which serves as both an optical absorber and conductor, while different, more conductive layers or portions (e.g., of the optical stack 16 or of other structures of the IMOD) can serve to bus signals between IMOD pixels. The optical stack 16 also can include one or more insulating or dielectric layers covering one or more conductive layers or a conductive/absorptive layer.

In some implementations, the layer(s) of the optical stack 16 can be patterned into parallel strips, and may form row electrodes in a display device as described further below. As will be understood by one having ordinary skill in the art, the term “patterned” is used herein to refer to masking as well as etching processes. In some implementations, a highly conductive and reflective material, such as aluminum (Al), may be used for the movable reflective layer 14, and these strips may form column electrodes in a display device. The movable reflective layer 14 may be formed as a series of parallel strips of a deposited metal layer or layers (orthogonal to the row electrodes of the optical stack 16) to form columns deposited on top of posts 18 and an intervening sacrificial material deposited between the posts 18. When the sacrificial material is etched away, a defined gap 19, or optical cavity, can be formed between the movable reflective layer 14 and the optical stack 16. In some implementations, the spacing between posts 18 may be approximately 1-1000 um, while the gap 19 may be less than 10,000 Angstroms (Å).

In some implementations, each pixel of the IMOD, whether in the actuated or relaxed state, is essentially a capacitor formed by the fixed and moving reflective layers. When no voltage is applied, the movable reflective layer 14 remains in a mechanically relaxed state, as illustrated by the IMOD 12 on the left in FIG. 1, with the gap 19 between the movable reflective layer 14 and optical stack 16. However, when a potential difference, e.g., voltage, is applied to at least one of a selected row and column, the capacitor formed at the intersection of the row and column electrodes at the corresponding pixel becomes charged, and electrostatic forces pull the electrodes together. If the applied voltage exceeds a threshold, the movable reflective layer 14 can deform and move near or against the optical stack 16. A dielectric layer (not shown) within the optical stack 16 may prevent shorting and control the separation distance between the layers 14 and 16, as illustrated by the actuated IMOD 12 on the right in FIG. 1. The behavior is the same regardless of the polarity of the applied potential difference. Though a series of pixels in an array may be referred to in some instances as “rows” or “columns,” a person having ordinary skill in the art will readily understand that referring to one direction as a “row” and another as a “column” is arbitrary. Restated, in some orientations, the rows can be considered columns, and the columns considered to be rows. Furthermore, the display elements may be evenly arranged in orthogonal rows and columns (an “array”), or arranged in non-linear configurations, for example, having certain positional offsets with respect to one another (a “mosaic”). The terms “array” and “mosaic” may refer to either configuration. Thus, although the display is referred to as including an “array” or “mosaic,” the elements themselves need not be arranged orthogonally to one another, or disposed in an even distribution, in any instance, but may include arrangements having asymmetric shapes and unevenly distributed elements.

FIG. 2 shows an example of a system block diagram illustrating an electronic device incorporating a 3×3 interferometric modulator display. The electronic device includes a processor 21 that may be configured to execute one or more software modules. In addition to executing an operating system, the processor 21 may be configured to execute one or more software applications, including a web browser, a telephone application, an email program, or other software application.

The processor 21 can be configured to communicate with an array driver 22. The array driver 22 can include a row driver circuit 24 and a column driver circuit 26 that provide signals to, e.g., a display array or panel 30. The cross section of the IMOD display device illustrated in FIG. 1 is shown by the lines 1-1 in FIG. 2. Although FIG. 2 illustrates a 3×3 array of IMODs for the sake of clarity, the display array 30 may contain a very large number of IMODs, and may have a different number of IMODs in rows than in columns, and vice versa.

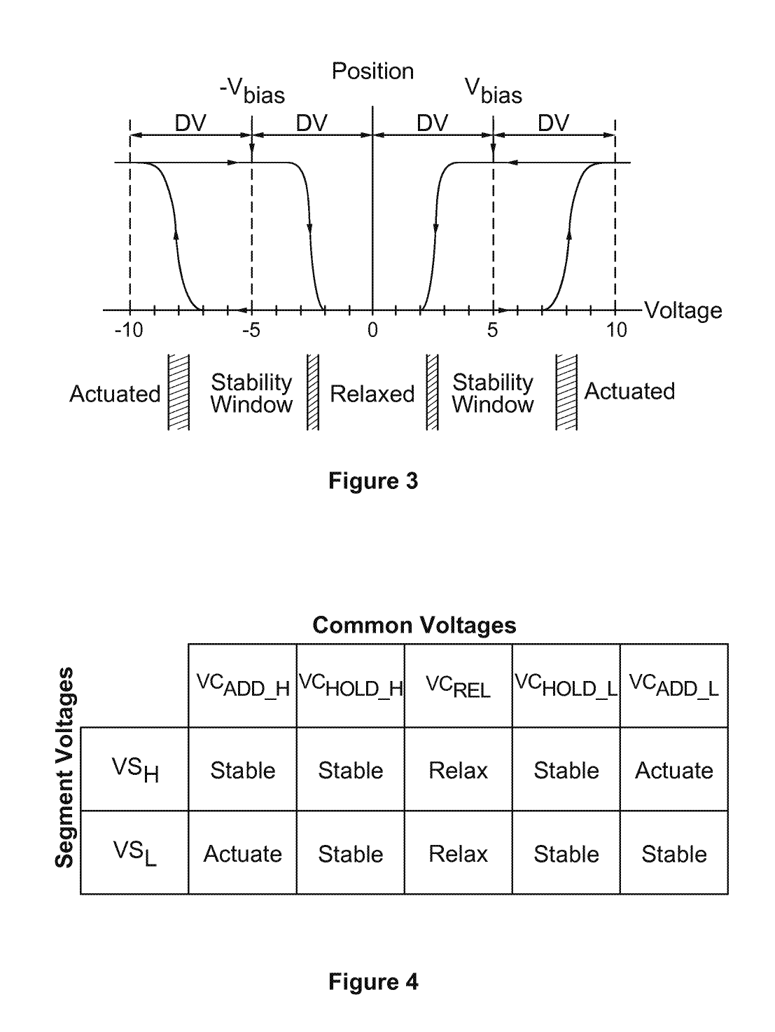

FIG. 3 shows an example of a diagram illustrating movable reflective layer position versus applied voltage for the interferometric modulator of FIG. 1. For MEMS interferometric modulators, the row/column (i.e., common/segment) write procedure may take advantage of a hysteresis property of these devices as illustrated in FIG. 3. An interferometric modulator may require, for example, about a 10-volt potential difference to cause the movable reflective layer, or mirror, to change from the relaxed state to the actuated state. When the voltage is reduced from that value, the movable reflective layer maintains its state as the voltage drops back below, e.g., 10 volts, however, the movable reflective layer does not relax completely until the voltage drops below 2 volts. Thus, a range of voltage, approximately 3 to 7 volts, as shown in FIG. 3, exists where there is a window of applied voltage within which the device is stable in either the relaxed or actuated state. This is referred to herein as the “hysteresis window” or “stability window.” For a display array 30 having the hysteresis characteristics of FIG. 3, the row/column write procedure can be designed to address one or more rows at a time, such that during the addressing of a given row, pixels in the addressed row that are to be actuated are exposed to a voltage difference of about 10 volts, and pixels that are to be relaxed are exposed to a voltage difference of near zero volts. After addressing, the pixels are exposed to a steady state or bias voltage difference of approximately 5-volts such that they remain in the previous strobing state. In this example, after being addressed, each pixel sees a potential difference within the “stability window” of about 3-7 volts. This hysteresis property feature enables the pixel design, e.g., illustrated in FIG. 1, to remain stable in either an actuated or relaxed pre-existing state under the same applied voltage conditions. Since each IMOD pixel, whether in the actuated or relaxed state, is essentially a capacitor formed by the fixed and moving reflective layers, this stable state can be held at a steady voltage within the hysteresis window without substantially consuming or losing power. Moreover, essentially little or no current flows into the IMOD pixel if the applied voltage potential remains substantially fixed.

In some implementations, a frame of an image may be created by applying data signals in the form of “segment” voltages along the set of column electrodes, in accordance with the desired change (if any) to the state of the pixels in a given row. Each row of the array can be addressed in turn, such that the frame is written one row at a time. To write the desired data to the pixels in a first row, segment voltages corresponding to the desired state of the pixels in the first row can be applied on the column electrodes, and a first row pulse in the form of a specific “common” voltage or signal can be applied to the first row electrode. The set of segment voltages can then be changed to correspond to the desired change (if any) to the state of the pixels in the second row, and a second common voltage can be applied to the second row electrode. In some implementations, the pixels in the first row are unaffected by the change in the segment voltages applied along the column electrodes, and remain in the state they were set to during the first common voltage row pulse. This process may be repeated for the entire series of rows, or alternatively, columns, in a sequential fashion to produce the image frame. The frames can be refreshed and/or updated with new image data by continually repeating this process at some desired number of frames per second.

The combination of segment and common signals applied across each pixel (that is, the potential difference across each pixel) determines the resulting state of each pixel. FIG. 4 shows an example of a table illustrating various states of an interferometric modulator when various common and segment voltages are applied. As will be readily understood by one having ordinary skill in the art, the “segment” voltages can be applied to either the column electrodes or the row electrodes, and the “common” voltages can be applied to the other of the column electrodes or the row electrodes.

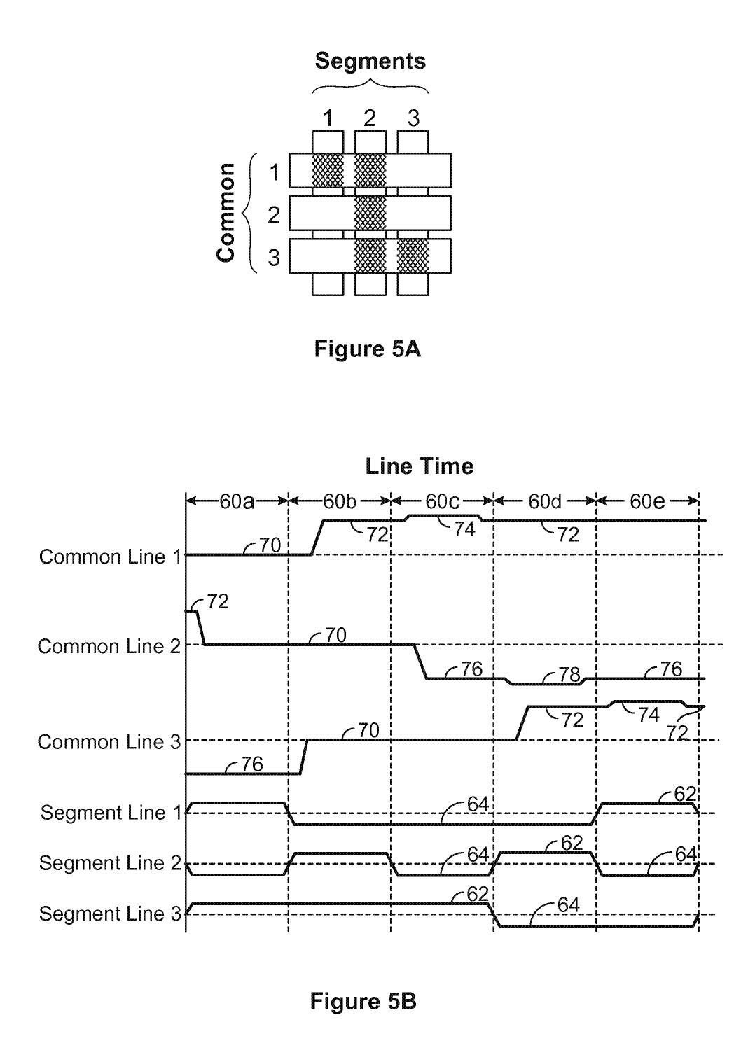

As illustrated in FIG. 4 (as well as in the timing diagram shown in FIG. 5B), when a release voltage VC_{REL} is applied along a common line, all interferometric modulator elements along the common line will be placed in a relaxed state, alternatively referred to as a released or unactuated state, regardless of the voltage applied along the segment lines, i.e., high segment voltage VS_{H} and low segment voltage VS_{L}. In particular, when the release voltage VC_{REL} is applied along a common line, the potential voltage across the modulator (alternatively referred to as a pixel voltage) is within the relaxation window (see FIG. 3, also referred to as a release window) both when the high segment voltage VS_{H} and the low segment voltage VS_{L} are applied along the corresponding segment line for that pixel.

When a hold voltage is applied on a common line, such as a high hold voltage VC_{HOLD}_{_{—}}_{H} or a low hold voltage VC_{HOLD L}, the state of the interferometric modulator will remain constant. For example, a relaxed IMOD will remain in a relaxed position, and an actuated IMOD will remain in an actuated position. The hold voltages can be selected such that the pixel voltage will remain within a stability window both when the high segment voltage VS_{H} and the low segment voltage VS_{L} are applied along the corresponding segment line. Thus, the segment voltage swing, i.e., the difference between the high VS_{H} and low segment voltage VS_{L}, is less than the width of either the positive or the negative stability window.

When an addressing, or actuation, voltage is applied on a common line, such as a high addressing voltage VC_{ADD H} or a low addressing voltage VC_{ADD L}, data can be selectively written to the modulators along that line by application of segment voltages along the respective segment lines. The segment voltages may be selected such that actuation is dependent upon the segment voltage applied. When an addressing voltage is applied along a common line, application of one segment voltage will result in a pixel voltage within a stability window, causing the pixel to remain unactuated. In contrast, application of the other segment voltage will result in a pixel voltage beyond the stability window, resulting in actuation of the pixel. The particular segment voltage which causes actuation can vary depending upon which addressing voltage is used. In some implementations, when the high addressing voltage VC_{ADD H} is applied along the common line, application of the high segment voltage VS_{H} can cause a modulator to remain in its current position, while application of the low segment voltage VS_{L} can cause actuation of the modulator. As a corollary, the effect of the segment voltages can be the opposite when a low addressing voltage VC_{ADD}_{—}_{L} is applied, with high segment voltage VS_{H} causing actuation of the modulator, and low segment voltage VS_{L} having no effect (i.e., remaining stable) on the state of the modulator.

In some implementations, hold voltages, address voltages, and segment voltages may be used which always produce the same polarity potential difference across the modulators. In some other implementations, signals can be used which alternate the polarity of the potential difference of the modulators. Alternation of the polarity across the modulators (that is, alternation of the polarity of write procedures) may reduce or inhibit charge accumulation which could occur after repeated write operations of a single polarity.

FIG. 5A shows an example of a diagram illustrating a frame of display data in the 3×3 interferometric modulator display of FIG. 2. FIG. 5B shows an example of a timing diagram for common and segment signals that may be used to write the frame of display data illustrated in FIG. 5A. The signals can be applied to the, e.g., 3×3 array of FIG. 2, which will ultimately result in the line time 60e display arrangement illustrated in FIG. 5A. The actuated modulators in FIG. 5A are in a dark-state, i.e., where a substantial portion of the reflected light is outside of the visible spectrum so as to result in a dark appearance to, e.g., a viewer. Prior to writing the frame illustrated in FIG. 5A, the pixels can be in any state, but the write procedure illustrated in the timing diagram of FIG. 5B presumes that each modulator has been released and resides in an unactuated state before the first line time 60a.

During the first line time 60a, a release voltage 70 is applied on common line 1; the voltage applied on common line 2 begins at a high hold voltage 72 and moves to a release voltage 70; and a low hold voltage 76 is applied along common line 3. Thus, the modulators (common 1, segment 1), (1,2) and (1,3) along common line 1 remain in a relaxed, or unactuated, state for the duration of the first line time 60a, the modulators (2,1), (2,2) and (2,3) along common line 2 will move to a relaxed state, and the modulators (3,1), (3,2) and (3,3) along common line 3 will remain in their previous state. With reference to FIG. 4, the segment voltages applied along segment lines 1, 2 and 3 will have no effect on the state of the interferometric modulators, as none of common lines 1, 2 or 3 are being exposed to voltage levels causing actuation during line time 60a (i.e., VC_{REL}—relax and VC_{HOLD}_{_{—}}_{L}—stable).

During the second line time 60b, the voltage on common line 1 moves to a high hold voltage 72, and all modulators along common line 1 remain in a relaxed state regardless of the segment voltage applied because no addressing, or actuation, voltage was applied on the common line 1. The modulators along common line 2 remain in a relaxed state due to the application of the release voltage 70, and the modulators (3,1), (3,2) and (3,3) along common line 3 will relax when the voltage along common line 3 moves to a release voltage 70.

During the third line time 60c, common line 1 is addressed by applying a high address voltage 74 on common line 1. Because a low segment voltage 64 is applied along segment lines 1 and 2 during the application of this address voltage, the pixel voltage across modulators (1,1) and (1,2) is greater than the high end of the positive stability window (i.e., the voltage differential exceeded a predefined threshold) of the modulators, and the modulators (1,1) and (1,2) are actuated. Conversely, because a high segment voltage 62 is applied along segment line 3, the pixel voltage across modulator (1,3) is less than that of modulators (1,1) and (1,2), and remains within the positive stability window of the modulator; modulator (1,3) thus remains relaxed. Also during line time 60c, the voltage along common line 2 decreases to a low hold voltage 76, and the voltage along common line 3 remains at a release voltage 70, leaving the modulators along common lines 2 and 3 in a relaxed position.

During the fourth line time 60d, the voltage on common line 1 returns to a high hold voltage 72, leaving the modulators along common line 1 in their respective addressed states. The voltage on common line 2 is decreased to a low address voltage 78. Because a high segment voltage 62 is applied along segment line 2, the pixel voltage across modulator (2,2) is below the lower end of the negative stability window of the modulator, causing the modulator (2,2) to actuate. Conversely, because a low segment voltage 64 is applied along segment lines 1 and 3, the modulators (2,1) and (2,3) remain in a relaxed position. The voltage on common line 3 increases to a high hold voltage 72, leaving the modulators along common line 3 in a relaxed state.

Finally, during the fifth line time 60e, the voltage on common line 1 remains at high hold voltage 72, and the voltage on common line 2 remains at a low hold voltage 76, leaving the modulators along common lines 1 and 2 in their respective addressed states. The voltage on common line 3 increases to a high address voltage 74 to address the modulators along common line 3. As a low segment voltage 64 is applied on segment lines 2 and 3, the modulators (3,2) and (3,3) actuate, while the high segment voltage 62 applied along segment line 1 causes modulator (3,1) to remain in a relaxed position. Thus, at the end of the fifth line time 60e, the 3×3 pixel array is in the state shown in FIG. 5A, and will remain in that state as long as the hold voltages are applied along the common lines, regardless of variations in the segment voltage which may occur when modulators along other common lines (not shown) are being addressed.

In the timing diagram of FIG. 5B, a given write procedure (i.e., line times 60a-60e) can include the use of either high hold and address voltages, or low hold and address voltages. Once the write procedure has been completed for a given common line (and the common voltage is set to the hold voltage having the same polarity as the actuation voltage), the pixel voltage remains within a given stability window, and does not pass through the relaxation window until a release voltage is applied on that common line. Furthermore, as each modulator is released as part of the write procedure prior to addressing the modulator, the actuation time of a modulator, rather than the release time, may determine the necessary line time. Specifically, in implementations in which the release time of a modulator is greater than the actuation time, the release voltage may be applied for longer than a single line time, as depicted in FIG. 5B. In some other implementations, voltages applied along common lines or segment lines may vary to account for variations in the actuation and release voltages of different modulators, such as modulators of different colors.

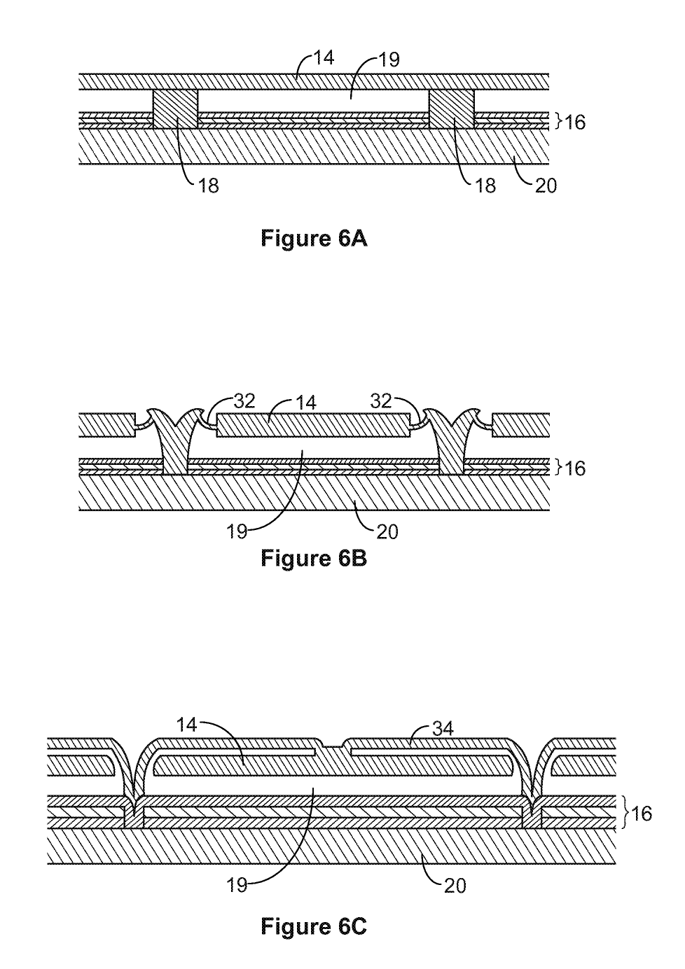

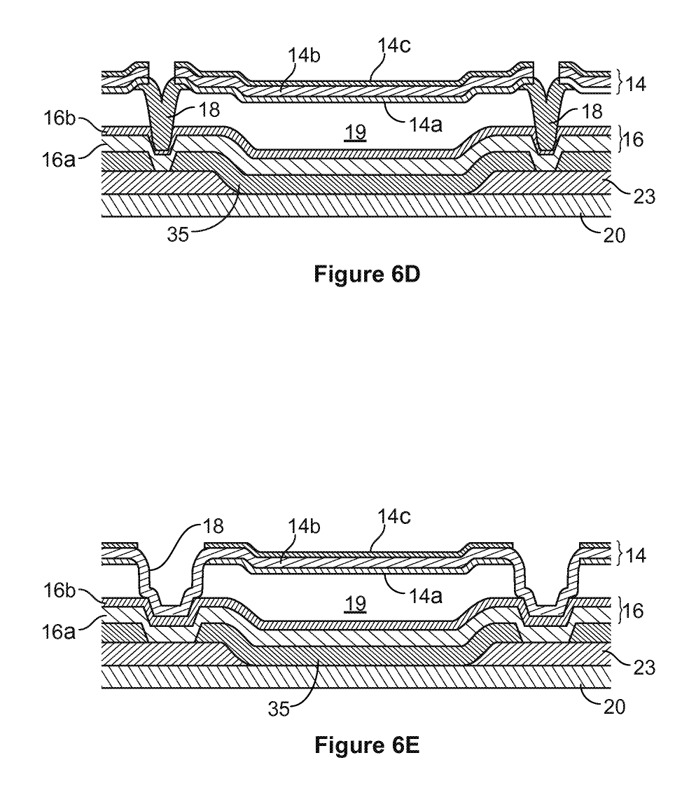

The details of the structure of interferometric modulators that operate in accordance with the principles set forth above may vary widely. For example, FIGS. 6A-6E show examples of cross-sections of varying implementations of interferometric modulators, including the movable reflective layer 14 and its supporting structures. FIG. 6A shows an example of a partial cross-section of the interferometric modulator display of FIG. 1, where a strip of metal material, i.e., the movable reflective layer 14 is deposited on supports 18 extending orthogonally from the substrate 20. In FIG. 6B, the movable reflective layer 14 of each IMOD is generally square or rectangular in shape and attached to supports at or near the corners, on tethers 32. In FIG. 6C, the movable reflective layer 14 is generally square or rectangular in shape and suspended from a deformable layer 34, which may include a flexible metal. The deformable layer 34 can connect, directly or indirectly, to the substrate 20 around the perimeter of the movable reflective layer 14. These connections are herein referred to as support posts. The implementation shown in FIG. 6C has additional benefits deriving from the decoupling of the optical functions of the movable reflective layer 14 from its mechanical functions, which are carried out by the deformable layer 34. This decoupling allows the structural design and materials used for the reflective layer 14 and those used for the deformable layer 34 to be optimized independently of one another.

FIG. 6D shows another example of an IMOD, where the movable reflective layer 14 includes a reflective sub-layer 14a. The movable reflective layer 14 rests on a support structure, such as support posts 18. The support posts 18 provide separation of the movable reflective layer 14 from the lower stationary electrode (i.e., part of the optical stack 16 in the illustrated IMOD) so that a gap 19 is formed between the movable reflective layer 14 and the optical stack 16, for example when the movable reflective layer 14 is in a relaxed position. The movable reflective layer 14 also can include a conductive layer 14c, which may be configured to serve as an electrode, and a support layer 14b. In this example, the conductive layer 14c is disposed on one side of the support layer 14b, distal from the substrate 20, and the reflective sub-layer 14a is disposed on the other side of the support layer 14b, proximal to the substrate 20. In some implementations, the reflective sub-layer 14a can be conductive and can be disposed between the support layer 14b and the optical stack 16. The support layer 14b can include one or more layers of a dielectric material, for example, silicon oxynitride (SiON) or silicon dioxide (SiO₂). In some implementations, the support layer 14b can be a stack of layers, such as, for example, a SiO₂/SiON/SiO₂ tri-layer stack. Either or both of the reflective sub-layer 14a and the conductive layer 14c can include, e.g., an aluminum (Al) alloy with about 0.5% copper (Cu), or another reflective metallic material. Employing conductive layers 14a, 14c above and below the dielectric support layer 14b can balance stresses and provide enhanced conduction. In some implementations, the reflective sub-layer 14a and the conductive layer 14c can be formed of different materials for a variety of design purposes, such as achieving specific stress profiles within the movable reflective layer 14.

As illustrated in FIG. 6D, some implementations also can include a black mask structure 23. The black mask structure 23 can be formed in optically inactive regions (e.g., between pixels or under posts 18) to absorb ambient or stray light. The black mask structure 23 also can improve the optical properties of a display device by inhibiting light from being reflected from or transmitted through inactive portions of the display, thereby increasing the contrast ratio. Additionally, the black mask structure 23 can be conductive and be configured to function as an electrical bussing layer. In some implementations, the row electrodes can be connected to the black mask structure 23 to reduce the resistance of the connected row electrode. The black mask structure 23 can be formed using a variety of methods, including deposition and patterning techniques. The black mask structure 23 can include one or more layers. For example, in some implementations, the black mask structure 23 includes a molybdenum-chromium (MoCr) layer that serves as an optical absorber, an SiO₂ layer, and an aluminum alloy that serves as a reflector and a bussing layer, with a thickness in the range of about 30-80 Å, 500-1000 Å, and 500-6000 Å, respectively. The one or more layers can be patterned using a variety of techniques, including photolithography and dry etching, including, for example, carbon tetrafluoromethane (CFO and/or oxygen (O₂) for the MoCr and SiO₂ layers and chlorine (Cl₂) and/or boron trichloride (BCl₃) for the aluminum alloy layer. In some implementations, the black mask 23 can be an etalon or interferometric stack structure. In such interferometric stack black mask structures 23, the conductive absorbers can be used to transmit or bus signals between lower, stationary electrodes in the optical stack 16 of each row or column. In some implementations, a spacer layer 35 can serve to generally electrically isolate the absorber layer 16a from the conductive layers in the black mask 23.

FIG. 6E shows another example of an IMOD, where the movable reflective layer 14 is self-supporting. In contrast with FIG. 6D, the implementation of FIG. 6E does not include support posts 18. Instead, the movable reflective layer 14 contacts the underlying optical stack 16 at multiple locations, and the curvature of the movable reflective layer 14 provides sufficient support that the movable reflective layer 14 returns to the unactuated position of FIG. 6E when the voltage across the interferometric modulator is insufficient to cause actuation. The optical stack 16, which may contain a plurality of several different layers, is shown here for clarity including an optical absorber 16a, and a dielectric 16b. In some implementations, the optical absorber 16a may serve both as a fixed electrode and as a partially reflective layer.

In implementations such as those shown in FIGS. 6A-6E, the IMODs function as direct-view devices, in which images are viewed from the front side of the transparent substrate 20, i.e., the side opposite to that upon which the modulator is arranged. In these implementations, the back portions of the device (that is, any portion of the display device behind the movable reflective layer 14, including, for example, the deformable layer 34 illustrated in FIG. 6C) can be configured and operated upon without impacting or negatively affecting the image quality of the display device, because the reflective layer 14 optically shields those portions of the device. For example, in some implementations a bus structure (not illustrated) can be included behind the movable reflective layer 14 which provides the ability to separate the optical properties of the modulator from the electromechanical properties of the modulator, such as voltage addressing and the movements that result from such addressing. Additionally, the implementations of FIGS. 6A-6E can simplify processing, such as, e.g., patterning.

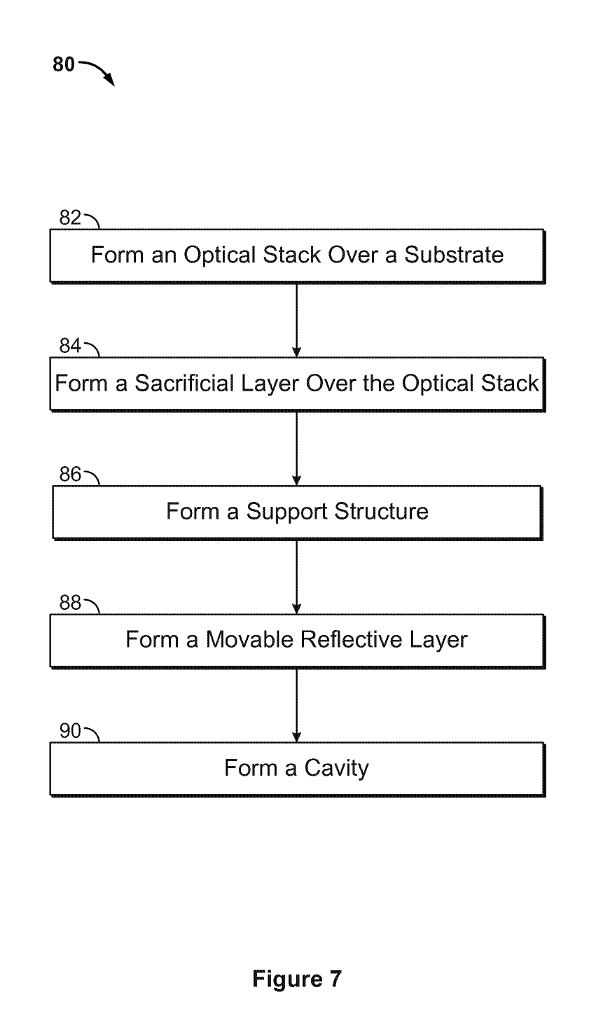

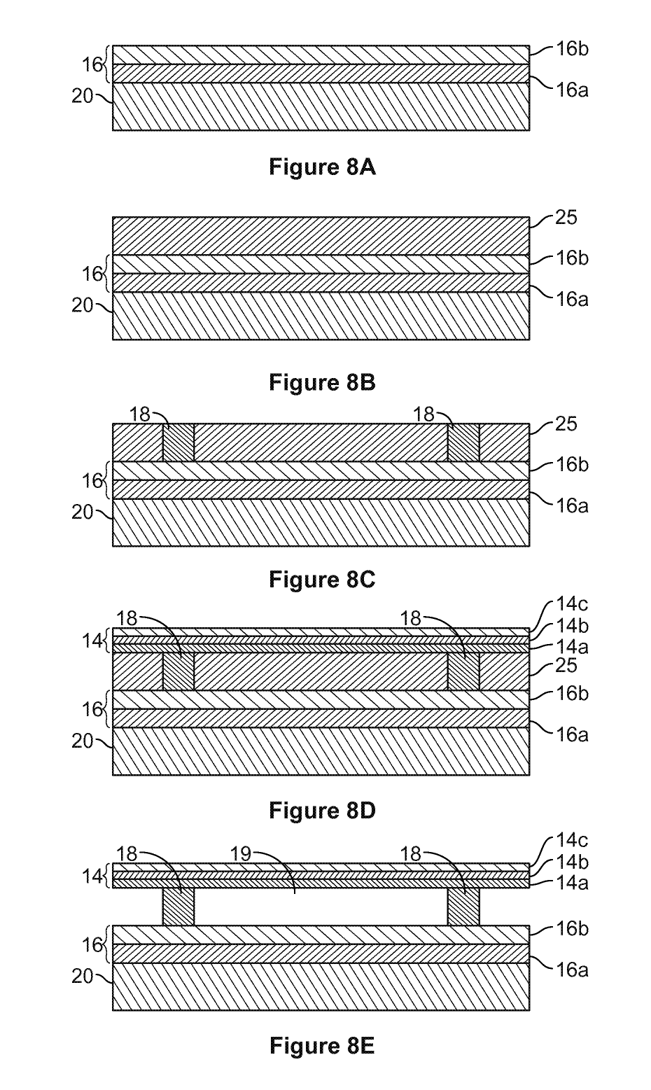

FIG. 7 shows an example of a flow diagram illustrating a manufacturing process 80 for an interferometric modulator, and FIGS. 8A-8E show examples of cross-sectional schematic illustrations of corresponding stages of such a manufacturing process 80. In some implementations, the manufacturing process 80 can be implemented to manufacture, e.g., interferometric modulators of the general type illustrated in FIGS. 1 and 6, in addition to other blocks not shown in FIG. 7. With reference to FIGS. 1, 6 and 7, the process 80 begins at block 82 with the formation of the optical stack 16 over the substrate 20. FIG. 8A illustrates such an optical stack 16 formed over the substrate 20. The substrate 20 may be a transparent substrate such as glass or plastic, it may be flexible or relatively stiff and unbending, and may have been subjected to prior preparation processes, e.g., cleaning, to facilitate efficient formation of the optical stack 16. As discussed above, the optical stack 16 can be electrically conductive, partially transparent and partially reflective and may be fabricated, for example, by depositing one or more layers having the desired properties onto the transparent substrate 20. In FIG. 8A, the optical stack 16 includes a multilayer structure having sub-layers 16a and 16b, although more or fewer sub-layers may be included in some other implementations. In some implementations, one of the sub-layers 16a, 16b can be configured with both optically absorptive and conductive properties, such as the combined conductor/absorber sub-layer 16a. Additionally, one or more of the sub-layers 16a, 16b can be patterned into parallel strips, and may form row electrodes in a display device. Such patterning can be performed by a masking and etching process or another suitable process known in the art. In some implementations, one of the sub-layers 16a, 16b can be an insulating or dielectric layer, such as sub-layer 16b that is deposited over one or more metal layers (e.g., one or more reflective and/or conductive layers). In addition, the optical stack 16 can be patterned into individual and parallel strips that form the rows of the display.

The process 80 continues at block 84 with the formation of a sacrificial layer 25 over the optical stack 16. The sacrificial layer 25 is later removed (e.g., at block 90) to form the cavity 19 and thus the sacrificial layer 25 is not shown in the resulting interferometric modulators 12 illustrated in FIG. 1. FIG. 8B illustrates a partially fabricated device including a sacrificial layer 25 formed over the optical stack 16. The formation of the sacrificial layer 25 over the optical stack 16 may include deposition of a xenon difluoride (XeF₂)-etchable material such as molybdenum (Mo) or amorphous silicon (Si), in a thickness selected to provide, after subsequent removal, a gap or cavity 19 (see also FIGS. 1 and 8E) having a desired design size. Deposition of the sacrificial material may be carried out using deposition techniques such as physical vapor deposition (PVD, e.g., sputtering), plasma-enhanced chemical vapor deposition (PECVD), thermal chemical vapor deposition (thermal CVD), or spin-coating.

The process 80 continues at block 86 with the formation of a support structure e.g., a post 18 as illustrated in FIGS. 1, 6 and 8C. The formation of the post 18 may include patterning the sacrificial layer 25 to form a support structure aperture, then depositing a material (e.g., a polymer or an inorganic material, e.g., silicon oxide) into the aperture to form the post 18, using a deposition method such as PVD, PECVD, thermal CVD, or spin-coating. In some implementations, the support structure aperture formed in the sacrificial layer can extend through both the sacrificial layer 25 and the optical stack 16 to the underlying substrate 20, so that the lower end of the post 18 contacts the substrate 20 as illustrated in FIG. 6A. Alternatively, as depicted in FIG. 8C, the aperture formed in the sacrificial layer 25 can extend through the sacrificial layer 25, but not through the optical stack 16. For example, FIG. 8E illustrates the lower ends of the support posts 18 in contact with an upper surface of the optical stack 16. The post 18, or other support structures, may be formed by depositing a layer of support structure material over the sacrificial layer 25 and patterning to remove portions of the support structure material located away from apertures in the sacrificial layer 25. The support structures may be located within the apertures, as illustrated in FIG. 8C, but also can, at least partially, extend over a portion of the sacrificial layer 25. As noted above, the patterning of the sacrificial layer 25 and/or the support posts 18 can be performed by a patterning and etching process, but also may be performed by alternative etching methods.

The process 80 continues at block 88 with the formation of a movable reflective layer or membrane such as the movable reflective layer 14 illustrated in FIGS. 1, 6 and 8D. The movable reflective layer 14 may be formed by employing one or more deposition processes, e.g., reflective layer (e.g., aluminum, aluminum alloy) deposition, along with one or more patterning, masking, and/or etching processes. The movable reflective layer 14 can be electrically conductive, and referred to as an electrically conductive layer. In some implementations, the movable reflective layer 14 may include a plurality of sub-layers 14a, 14b, 14c as shown in FIG. 8D. In some implementations, one or more of the sub-layers, such as sub-layers 14a, 14c, may include highly reflective sub-layers selected for their optical properties, and another sub-layer 14b may include a mechanical sub-layer selected for its mechanical properties. Since the sacrificial layer 25 is still present in the partially fabricated interferometric modulator formed at block 88, the movable reflective layer 14 is typically not movable at this stage. A partially fabricated IMOD that contains a sacrificial layer 25 also may be referred to herein as an “unreleased” IMOD. As described above in connection with FIG. 1, the movable reflective layer 14 can be patterned into individual and parallel strips that form the columns of the display.

The process 80 continues at block 90 with the formation of a cavity, e.g., cavity 19 as illustrated in FIGS. 1, 6 and 8E. The cavity 19 may be formed by exposing the sacrificial material 25 (deposited at block 84) to an etchant. For example, an etchable sacrificial material such as Mo or amorphous Si may be removed by dry chemical etching, e.g., by exposing the sacrificial layer 25 to a gaseous or vaporous etchant, such as vapors derived from solid XeF₂ for a period of time that is effective to remove the desired amount of material, typically selectively removed relative to the structures surrounding the cavity 19. Other combinations of etchable sacrificial material and etching methods, e.g. wet etching and/or plasma etching, also may be used. Since the sacrificial layer 25 is removed during block 90, the movable reflective layer 14 is typically movable after this stage. After removal of the sacrificial material 25, the resulting fully or partially fabricated IMOD may be referred to herein as a “released” IMOD.

Some EMS devices may include a movable layer (also referred to as a deformable layer) separated from a substrate, with the substrate and the movable layer (or other structures associated with the movable layer) defining a cavity there between. For example, some of the IMODs described herein include movable reflective layers. Other examples of EMS devices that may include a movable layer include other display devices, RF devices, pressure sensing devices, and biochemical devices. In the operation of an EMS device, the movable layer may move into and/or out of the cavity in response to a voltage (e.g., an actuation voltage or a release voltage) or other signal. Alternatively, the movable layer may move into or out of the cavity in response to a change in an environmental condition, such as pressure, humidity, temperature, etc. In the case of a pressure sensing EMS device, for example, the movable layer may move into and/or out of the cavity in response to a change in the pressure being monitored. In some implementations, the movable layer or a component associated with the movable layer may come into and out of contact with the substrate or layers on the substrate as a result of the movement of the movable layer.

The stiffness of a movable layer may be defined as the resistance of the movable layer to deformation and/or motion by an applied force. The stiffness of the movable layer may be important in the operation of the EMS device. For example, for an IMOD, the stiffness of the movable layer may affect the actuation voltage of the IMOD, with a stiffer movable layer generally using a higher actuation voltage. As another example, for an EMS pressure sensing device, pressure may cause a movable layer to move into and out of a cavity, with the amount that the movable layer moves being correlated to the pressure. Thus, stiffer movable layers, which may move less for a given pressure, may be used to measure higher pressures. Further, as the size of an EMS device is reduced, the stiffness of a movable layer in the EMS device may increase.

As noted herein, the stiffness of a movable layer may depend in part on the thickness of the movable layer and residual stresses that may be present in the movable layer. In some EMS devices, the thickness of the movable layer may be defined by the EMS device design, and the residual stresses in the movable layer may be determined by the processes used to fabricate the movable layer and/or to fabricate other EMS device components. For example, residual stresses may be present in the movable layer (e.g., in material layers making up the movable layer, such as metal layers and dielectric layers) due to thermal treatments used in the fabrication of the EMS device. The stiffness of the movable layer also may be controlled or tuned by features formed in the movable layer, as described herein. Features in a movable layer may be used to adjust the stiffness of the movable layer, in addition to or alternatively to reducing the thickness of the movable layer or to changing the fabrication operations used to form an EMS device.

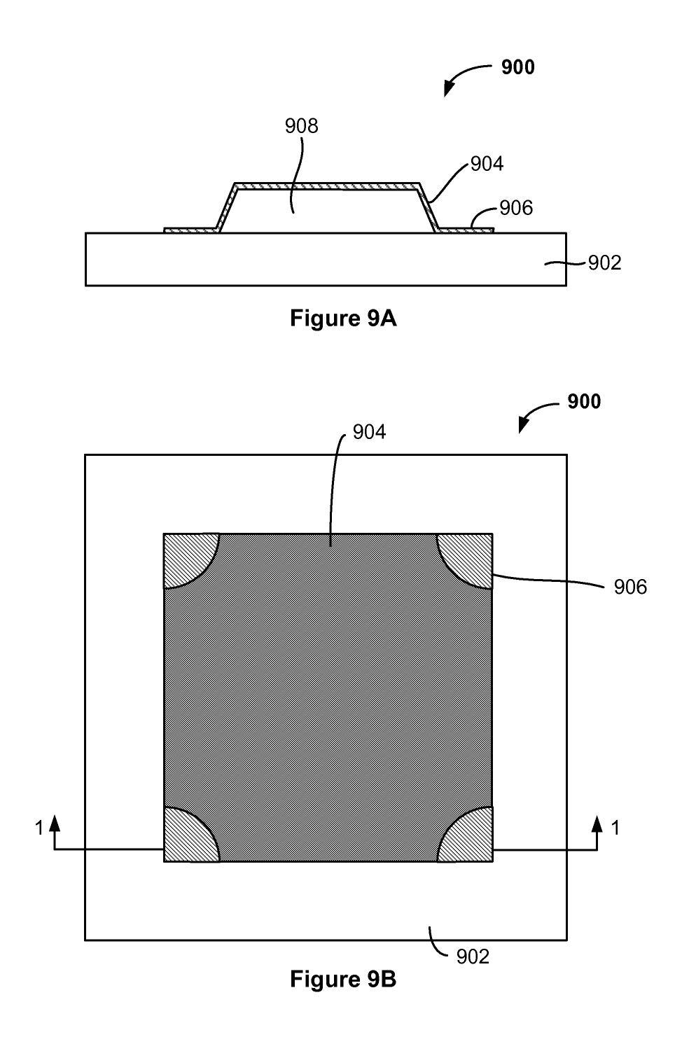

FIGS. 9A and 9B show examples of schematic illustrations of an electromechanical systems (EMS) device. FIG. 9A shows an example of a cross-sectional schematic illustration of an EMS device 900. The EMS device 900 includes a substrate 902 and a movable layer 904 over the substrate. The EMS device 900 may include different layers of material (not shown) associated with the substrate 902 and the movable layer 904 may include multiple layers of material (not shown), depending on the function of the EMS device 900. The movable layer 904 may contact the surface of the substrate 902 at anchor points 906. The movable layer 904 and the substrate 902 may define a cavity 908. The movable layer 904 may move into the cavity 908 (e.g., collapse the cavity) or move out from the cavity 908 (e.g., expand the cavity), depending on the function and operation of the EMS device 900.

The EMS device 900 may be similar to the IMOD shown in FIG. 6E. For example, additional layers of material (not shown) on the substrate 902 may include an optical stack including an optical absorber and a dielectric, as described with respect to FIGS. 6D and 6E. The movable layer 904 may include multiple layers of material (not shown), such as a conductive layer, a support layer, and a reflective sub-layer, as described with respect to FIG. 6D.

The substrate 902 may be any number of different substrate materials, including transparent materials and non-transparent materials. In some implementations, the substrate may be silicon, silicon-on-insulator (SOI), a glass (for example, a display glass or a borosilicate glass), a flexible plastic, or a metal foil. In some implementations, the substrate on which an EMS device is fabricated has dimensions of a few microns to tens of centimeters.

FIG. 9B shows an example of a top-down schematic illustration of the EMS device 900. The EMS device 900 includes the substrate 902 and the movable layer 904. As noted above, the movable layer 904 contacts the surface of the substrate 902 at anchor points 906. The cross-sectional schematic illustration of the EMS device 900 shown in FIG. 9A is a view though line 1-1 of FIG. 9B.

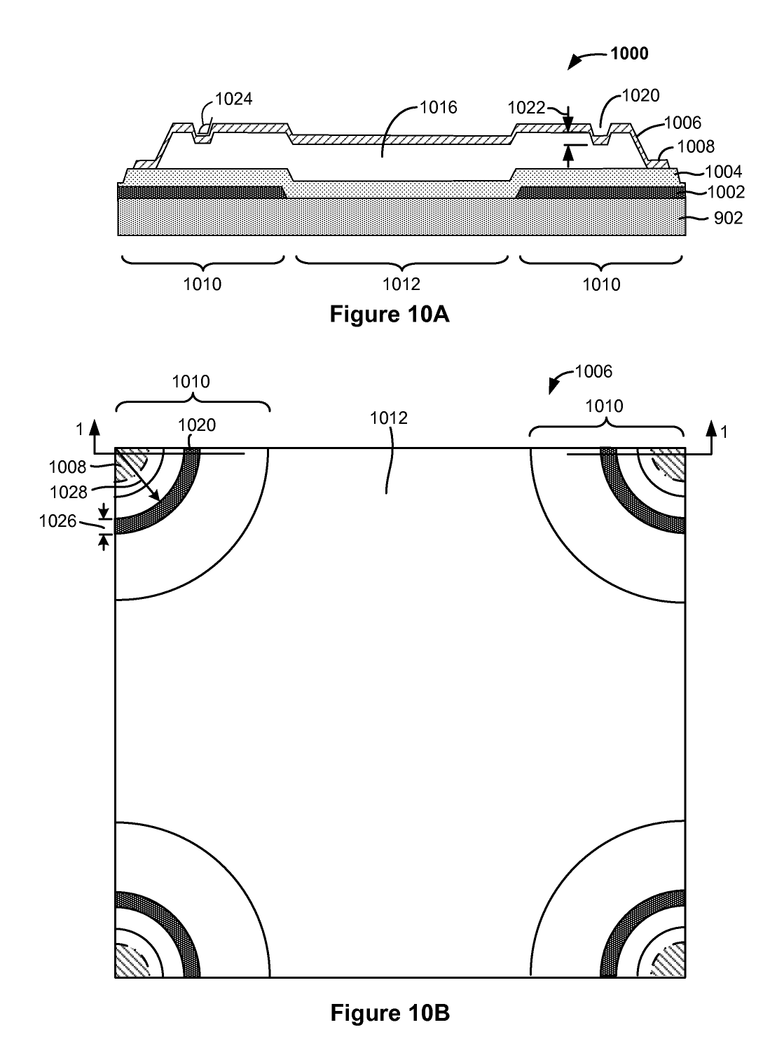

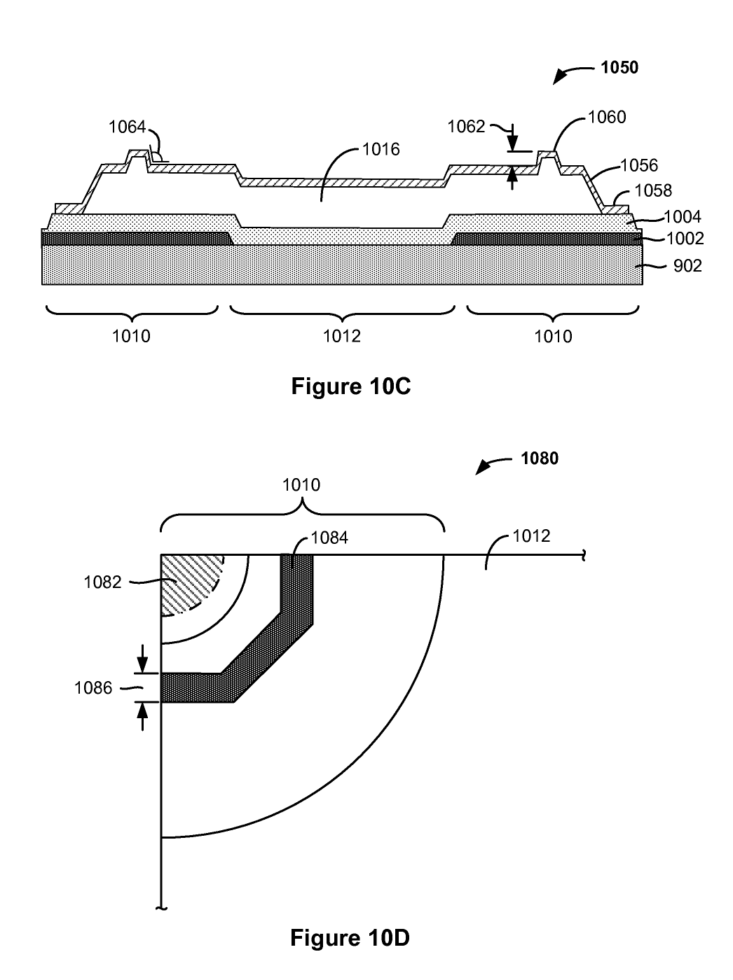

FIGS. 10A-10D show examples of schematic illustrations of EMS devices including a movable layer having a feature associated with each anchor point of the movable layer. FIG. 10A shows an example of a cross-sectional schematic illustration of an EMS device 1000, and FIG. 10B shows an example of a top-down schematic illustration of a movable layer 1006 of the EMS device 1000. The cross-sectional schematic illustration of the EMS device 1000 shown in FIG. 10A is a view though line 1-1 of FIG. 10B. The EMS device shown in FIGS. 10A and 10B may be an IMOD or other EMS reflective display device, which may be similar to the IMOD shown in FIG. 6E, in some implementations. As noted herein, however, features also may be included in the movable layers of any number of other EMS devices to adjust the stiffness of a movable layer.

Turning first to FIG. 10A, the EMS device 1000 includes a substrate 902, layers 1002 and 1004 disposed on the substrate 902, and the movable layer 1006. In some implementations, the movable layer 1006 may be a movable reflective layer, such as the movable reflective layer 14 shown in FIGS. 6D and 6E. In some implementations, the layer 1002 may include a black mask structure, as described with respect to FIG. 6D. In some implementations, the layer 1004 may include a spacer layer and an optical stack, as described with respect to FIG. 6D. The optical stack may include an optical absorber layer and a dielectric layer. The movable layer 1006 may contact and/or be attached to the layer 1004 disposed on the substrate 902 at anchor points 1008.

In some implementations, the movable layer 1006 may be a tri-layer structure including a mirror, a dielectric layer, and a cap, for example, an Al/SiON/Al tri-layer. In some implementations, the movable layer 1006 may be a bilayer structure including an Al layer and a nickel (Ni) layer. In some implementations, the movable layer 1006 may be a structure including a mirror, a first dielectric layer, a cap, and a second dielectric layer. The movable layer 1006 may be about 100 nanometers (nm) to 10 microns thick.

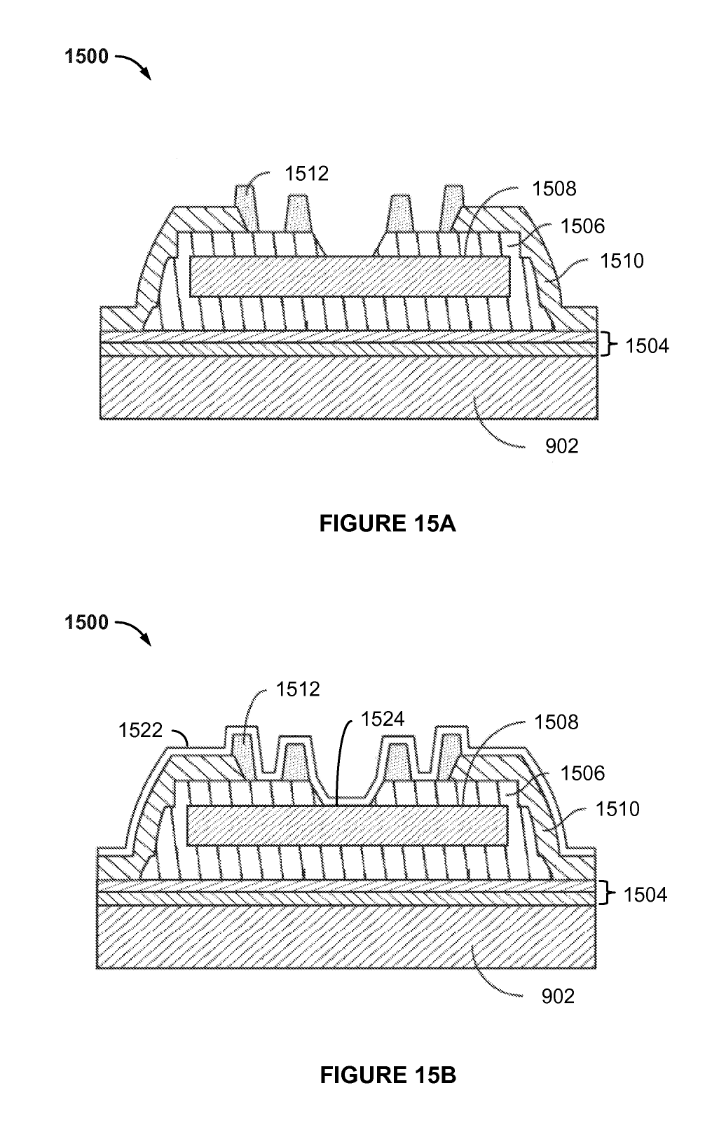

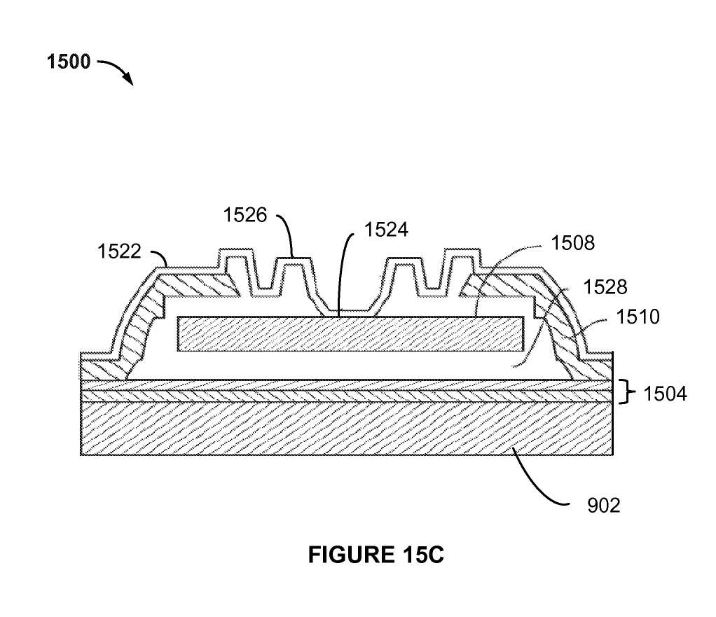

In some implementations, the movable layer 1006 may have selected mechanical properties as well as, for example, optical properties, to enable operation of the EMS device 1000. As described above with reference to the example of the IMOD shown in FIG. 6C, however, optical functions of the movable reflective layer 14 can be decoupled from its mechanical functions. The mechanical functions may be performed by the deformable layer 34. Implementations of EMS devices similar to the IMOD shown in FIG. 6C are described further below with respect to FIGS. 15A-15C.

The EMS device 1000 includes inactive regions 1010 and an active region 1012. The inactive regions 1010 are regions that are inactive during operation of the EMS device 1000 and the active region 1012 is a region that is active during operation of the EMS device 1000. For example, when the layer 1002 is a black mask structure, the inactive regions 1010 may be optically inactive regions and the active region 1012 may be an optically active region. An optically inactive region may be a region that absorbs light, and an optically active region may be a region that reflects light. As another example, with an EMS device that is a pressure sensor, active regions may be regions that are able to produce a signal that can be correlated to pressure, and inactive regions may be regions that include additional circuitry and/or mechanical support for the active region. In some implementations, the inactive regions 1010 may have a lateral dimension of about 2 microns to 25 microns, not including the length occupied by the anchor points 1008. In some implementations, the active region 1012 also may have a lateral dimension of about 2 microns to 25 microns.

The movable layer 1006 and the layer 1004 disposed on the substrate 902 may define a cavity 1016. In some implementations, the height of the cavity 1016 (i.e., the distance between the movable layer 1006 and the substrate 902 and/or layers 1002 and/or 1004 on the substrate 902) may be about 0.1 microns to 10 microns. In some other implementations, the height of the cavity 1016 may be less than about 1 micron. In the operation of the EMS device 1000, the movable layer 1006 may move into the cavity 1016 and back into the position shown in FIG. 10A. The stiffness of the movable layer 1006, which may be set by the design of the EMS device 1000 and the manufacturing process of the EMS device 1000, also may be modified and/or tuned (e.g., the stiffness may be increased or decreased) with features associated with the anchor points 1008 in the movable layer 1006.

In the cross-sectional schematic illustration shown in FIG. 10A, two features 1020 are included in the movable layer 1006. The features 1020 may protrude into the cavity 1016. In some implementations, a dimension 1022 of the features 1020 (e.g., a depth of the features 1020 protruding into the cavity 1016) may be about 50 nm to 1 micron. In some implementations, a dimension 1022 of the features 1020 may depend on the material layer or layers of the movable layer 1016. In some implementations, an angle 1024 that a planar portion of the movable layer 1006 (i.e., a portion of the movable 1006 layer that may be substantially parallel to the surface of the substrate 902) makes with a sloped portion of the movable layer 1006 may be about 100 degrees to 150 degrees or about 120 degrees to 135 degrees.

FIG. 10B shows an example a top-down schematic illustration of the movable layer 1006 of the EMS device 1000. In some implementations, the movable layer 1006 may be substantially square. As shown in FIG. 10B, the movable layer 1006 overlies the active region 1012 and the inactive regions 1010 of the EMS device 1000. The inactive regions 1010 correspond to the one quarter of a circle shown in FIG. 10B in each corner of the movable layer 1006. In some implementations, in order to not affect the properties of the active region 1012, the features 1020 in the movable layer 1006 may be within the inactive regions 1010. In some other implementations, the features 1020 in the movable layer may be in the active region 1012 or be in both the inactive regions 1010 and the active region 1012. Also in the inactive regions 1010 are the anchor points 1008. In some implementations, the features 1020 in the movable layer 1006 substantially may form an arc associated with each of the anchor points 1008. The features 1020 in the example of FIG. 10B each form an arc that extends around an anchor point 1008. In some implementations, a dimension 1026 of the arc of each of the features 1020 (e.g., a width of each of the features 1020) may be about 2 microns to 10 microns. In some implementations, a dimension 1026 of the arc of each of the features 1020 may be about as wide as the lithography process resolution of the fabrication facility used to fabricate the EMS device 1000. In some implementations, a radius 1028 of the arc of each of the features 1020 may be about 2 microns to 25 microns. A dimension of the edge of the side of the substantially square movable layer 1006 may be about 5 microns (e.g., forming a 5 micron by 5 micron square) to about 1 millimeter (mm) (e.g., forming a 1 mm by 1 mm square).

The features 1020 in the movable layer 1006 may decrease a force that causes the movable layer 1006 to move. For example, the movable layer 1006 of the EMS device 1000 may move into the cavity 1016 when an actuation voltage is applied across the movable layer 1016 and the substrate 902 or layers on the substrate 902. The features 1020 may decrease the stiffness of the movable layer 1006 and hence decrease the actuation voltage needed to cause the movable layer 1016 to move. In some implementations, as the depth (i.e., the dimension 1022) of the features 1020 increases, the stiffness of the movable layer 1006 may further decrease. In some implementations, as the angle 1024 increases (e.g., increases to about 180 degrees), the effect of the features 1020 in reducing the stiffness of the movable layer 1006 may be reduced (i.e., as the angle 1024 approaches about 180 degrees, there may be little or no reduction in the stiffness of the movable layer 1006).

In some implementations, each of the features 1020 associated with each of the anchor points 1008 may be substantially the same. With such a configuration, the active region 1012 of the movable layer 1006 may move into the cavity 1016 in a manner such that the movable layer 1006 in the active region 1012 may be substantially parallel to the surface of the substrate 902. In some other implementations, the features 1020 associated with each of the anchor points 1008 may not be substantially similar. With such a configuration, the active region 1012 of the movable layer 1006 may move into the cavity 1016 in a manner such that the movable layer 1006 in the active region 1012 may not be substantially parallel to the surface of the substrate 902. For example, one or more sides of the active region 1012 of the movable layer 1006 may deform more than one or more other sides.

FIG. 10C shows another example of a cross-sectional schematic illustration of an EMS device 1050. The EMS device 1050 may be similar to the EMS device 1000 shown in FIG. 10A, except for that the features in the movable layer of the EMS device 1050 may protrude out from a cavity 1016 defined by a movable layer 1056 and a substrate 902.

The EMS device 1050 shown in FIG. 10C includes the substrate 902, layers 1002 and 1004 disposed on the substrate 902, and the movable layer 1056. In some implementations, the movable layer 1056 may be a movable reflective layer. The movable layer 1056 may contact and/or be attached to the layer 1004 disposed on the substrate 902 at anchor points 1058. In the cross-sectional schematic illustration shown in FIG. 10C, two features 1060 are included in the movable layer 1056. The features 1060 may protrude out from the cavity 1016 defined by the movable layer 1056 and the layer 1004 disposed on the substrate 902. In some implementations, a dimension 1062 of the features 1060 (e.g., a height of the features 1060 protruding out from the cavity 1016) may be about 50 nm to 1 micron. In some implementations, a dimension 1062 of the features 1060 may depend on the material layer or layers of the movable layer 1056. In some implementations, an angle 1064 that a planar portion of the movable layer 1056 (i.e., a portion of the movable 1056 layer that may be substantially parallel to the surface of the substrate 902) makes with a sloped portion of the movable layer 1056 may be about 100 degrees to 150 degrees or about 120 degrees to 135 degrees.

The features 1056 in the movable layer 1060 may decrease a force that causes the movable layer 1056 to move by decreasing the stiffness of the movable layer 1056. In some implementations, as the height (i.e., the dimension 1062) of the features 1060 increases, the stiffness of the movable layer 1056 may further decrease. In some implementations, as the angle 1064 increases (e.g., increases to about 180 degrees), the effect of the features 1060 in reducing the stiffness of the movable layer 1056 may be reduced (i.e., as the angle 1064 approaches about 180 degrees, there may be little or no reduction in the stiffness of the movable layer 1056).

In some implementations, in order to not affect the properties of the active region 1012, the features 1060 in the movable layer 1056 may be within inactive regions 1010 of the EMS device 1050. The features 1060 in the movable layer 1056 may have a similar configuration as the features 1020 in the movable layer 1006 shown in FIG. 10B. For example, in some implementations, the features 1060 in the movable layer 1056 substantially may form an arc associated with each of the anchor points 1058 and may have similar dimensions as the features 1020.

FIG. 10D shows an example of a top-down schematic illustration of an anchor point of a movable layer of an EMS device and a feature associated with the anchor point. As shown in FIG. 10D, a portion of a movable layer 1080 may include an anchor point 1082 and a feature 1084 associated with the anchor point 1082. In some implementations, the feature 1084 in the movable layer 1080 substantially may form the perimeter of one quarter of an octagon that is centered approximately at a center of the anchor point 1082. The movable layer 1080 also overlies an active region 1012 and an inactive region 1010 of the EMS device. The inactive region 1010 in the example of FIG. 10D includes the one quarter of a circle in the movable layer 1080 shown in FIG. 10D. In the inactive region 1010 are the anchor point 1082 and the feature 1084. In some implementations, a dimension 1086 of the feature 1084 (e.g., a width of the feature 1084) may be about 2 microns to 10 microns. In some implementations, the feature 1084 may be about 2 microns to 25 microns from a center point of the anchor point 1082.

The feature 1084 in the movable layer 1080 may decrease a force that causes the movable layer 1080 to move by decreasing the stiffness of the movable layer 1080. Features similar to the features 1020 shown in FIG. 10B or the feature 1084 shown in FIG. 10D may be formed in the movable layer of an EMS device. In some implementations, the features 1020 shown in FIG. 10B (i.e., arc-shaped features) or the feature 1084 shown in FIG. 10D (i.e., an octagon-shaped feature) formed in the movable layer of an EMS device may aid in the symmetry of actuation of the EMS device.

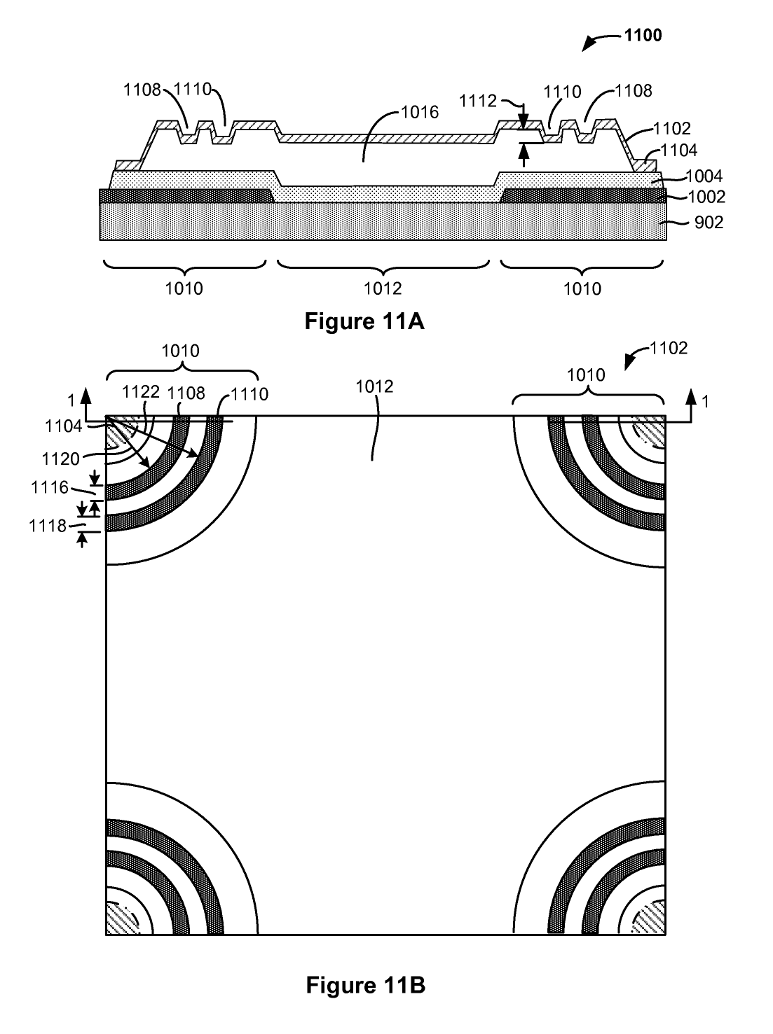

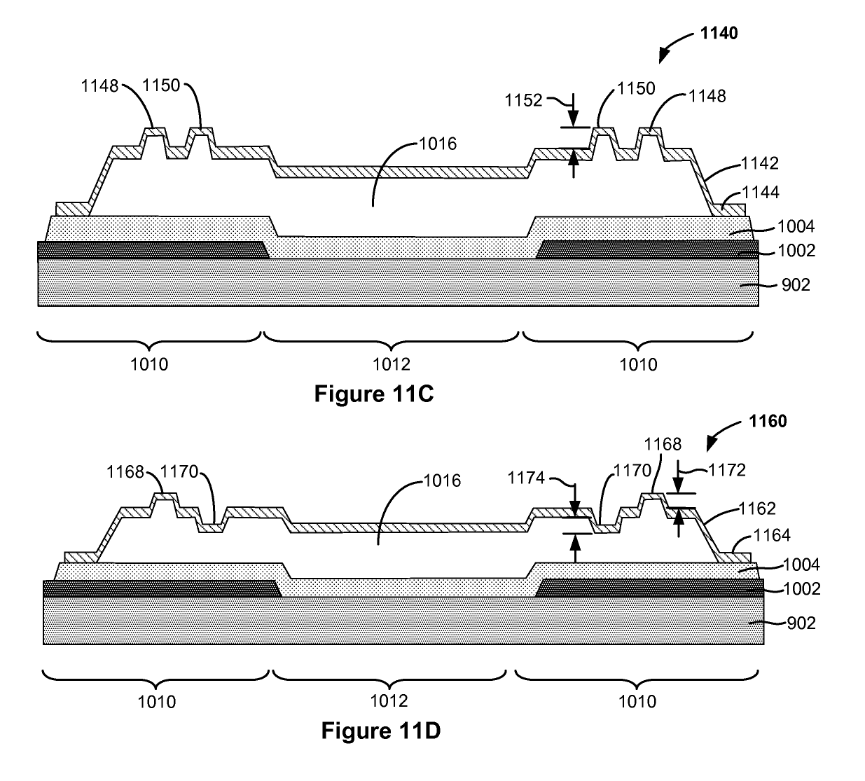

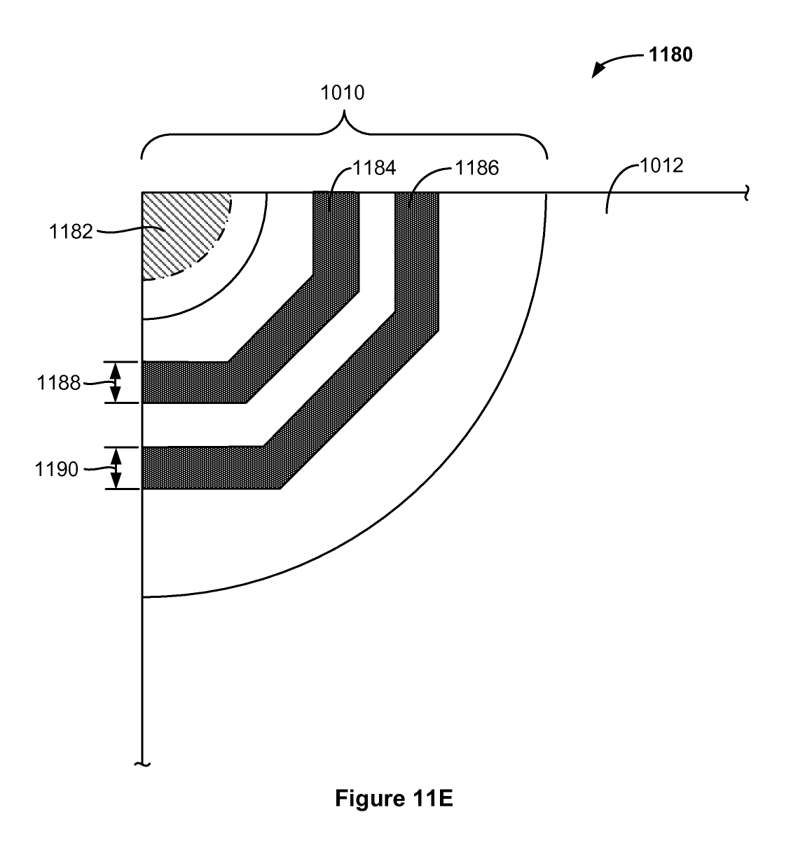

FIGS. 11A-11E show examples of schematic illustrations of EMS devices including a movable layer having two features associated with each anchor point of the movable layer. FIG. 11A shows an example of a cross-sectional schematic illustration of an EMS device 1100, and FIG. 11B shows an example of a top-down schematic illustration of a movable layer 1102 of the EMS device 1100. The cross-sectional schematic illustration of the EMS device 1100 shown in FIG. 11A is a view though line 1-1 of FIG. 11B. The EMS device shown in FIGS. 11A and 11B may be an IMOD or other EMS reflective display device, which may be similar to the IMOD shown in FIG. 6E, in some implementations.

In some implementations, the EMS devices and the movable layers shown in FIGS. 11A-11E may be similar to the EMS devices and the movable layers shown in FIGS. 10A-10D, with an additional feature associated with each anchor point of the movable layers 1102, 1142, and 1162. Two features associated with each anchor point of the movable layers 1102, 1142, and 1162 may further decrease the stiffness of the movable layers 1102, 1142, and 1162 compared to a single feature associated with each anchor point.

Turning first to FIG. 11A, the EMS device 1100 includes a substrate 902, layers 1002 and 1004 disposed on the substrate 902, and the movable layer 1102. In some implementations, the movable layer 1102 may be a movable reflective layer. The movable layer 1102 may contact and/or be attached to the layer 1004 disposed on the substrate 902 at anchor points 1104. In the cross-sectional schematic illustration shown in FIG. 11A, four features 1108 and 1110 are formed in the movable layer 1102. The features 1108 and 1110 may protrude into a cavity 1016 defined by the movable layer 1102 and the layer 1004 disposed on the substrate 902. In some implementations, a dimension 1112 of the features 1108 and 1110 (e.g., a depth of the features 1108 and 1110 protruding into the cavity 1016) may be about 50 nm to 1 micron. In some implementations, the dimension 1112 of the features 1108 may be different than the dimension 1112 of the features 1110. In some implementations, an angle that a planar portion of the movable layer 1102 (i.e., a portion of the movable layer 1102 that may be substantially parallel to the surface of the substrate 902) makes with a sloped portion of the movable layer 1102 may be about 100 degrees to 150 degrees or about 120 degrees to 135 degrees.

The features 1108 and 1110 in the movable layer 1102 may decrease a force that causes the movable layer 1102 to move by decreasing the stiffness of the movable layer 1102. In some implementations, in order to not affect the optical properties of an active region 1012, the features 1108 and 1110 in the movable layer 1102 may be confined within inactive regions 1010 of the EMS device 1100.

FIG. 11 B shows an example of a top-down schematic illustration of the movable layer 1102 of the EMS device 1100. In some implementations, the movable layer 1102 may be substantially square. As shown in FIG. 11B, the movable layer 1102 overlies the active region 1012 and the inactive regions 1010 of the EMS device 1100. The inactive regions 1010 may be located at the four corners of the movable layer 1102, with each of the inactive regions 1010 have a shape of a quarter circle. In some implementations, in order to not affect the optical properties of the active region 1012, the features 1108 and 1110 in the movable layer 1102 may be confined within the inactive regions 1010. Also in the inactive regions 1010 are the anchor points 1104. In some implementations, the features 1108 and 1110 in the movable layer 1102 substantially may form arcs associated with each of the anchor points 1104. In some implementations, a dimension 1116 and 1118 of the arc of each of the features 1108 and 1110 (e.g., a width of the features 1108 and 1110), respectively, may be about 2 microns to 10 microns. In some implementations, a radius 1120 and 1122 of the arc of each of the features 1108 and 1110, respectively, may be about 2 microns to 25 microns, with the radius 1120 being smaller than the radius 1122. A dimension of the edge of the side of the substantially square movable layer 1102 may be about 5 microns (e.g., forming a 5 micron by 5 micron square) to about 1 mm (e.g., forming a 1 mm by 1 mm square).

In some implementations, each of the features 1108 associated with each of the anchor points 1104 may be substantially the same. In some implementations, each of the features 1110 associated with each of the anchor points 1104 may be substantially the same. With such a configuration, the active region 1012 of the movable layer 1102 may move into the cavity 1016 in a manner that the movable layer in the active region 1012 may be substantially parallel to the surface of the substrate 902. In some other implementations, each of the features 1108 and/or each of the features 1110 associated with each of the anchor points 1104 may not be substantially similar. With such a configuration, the active region 1012 of the movable layer 1102 may move into the cavity 1016 in a manner that the movable layer 1102 in the active region 1012 may not be substantially parallel to the surface of the substrate 902.

FIGS. 11C and 11D show further examples of cross-sectional schematic illustrations of EMS devices 1140 and 1160, respectively. The EMS device 1140 may be similar to the EMS device 1100 shown in FIG. 11A, except for that the features in a movable layer 1142 of the EMS device 1140 may protrude out from a cavity 1016 defined by the movable layer 1142 and a substrate 902. The EMS device 1160 may be similar to the EMS device 1100 shown in FIG. 11A, except for that the features in a movable layer 1162 of the EMS device 1160 may protrude both into and out from a cavity 1016 defined by the movable layer 1162 and a substrate 902.

Turning to FIG. 11C, the EMS device 1140 includes the substrate 902, layers 1002 and 1004 disposed on the substrate 902, and the movable layer 1142. In some implementations, the movable layer 1142 may be a movable reflective layer. The movable layer 1142 may contact and/or be attached to the layer 1004 disposed on the substrate 902 at anchor points 1144. In the cross-sectional schematic illustration shown in FIG. 11C, four features 1148 and 1150 are included in the movable layer 1142. The features 1148 and 1150 may protrude out from the cavity 1016 defined by the movable layer 1142 and the layer 1004 disposed on the substrate 902. In some implementations, a dimension 1152 of the features 1148 and 1150 (e.g., a height of the features 1148 and 1150 protruding out from the cavity 1016) may be about 50 nm to 1 micron. In some implementations, the dimension 1152 of the features 1148 may be different than the dimension 1152 of the features 1150. In some implementations, an angle that a planar portion of the movable layer 1142 (i.e., a portion of the movable layer 1142 that may be substantially parallel to the surface of the substrate 902) makes with a sloped portion of the movable layer 1142 may be about 100 degrees to 150 degrees or about 120 degrees to 135 degrees.

The features 1148 and 1150 in the movable layer 1142 may decrease a force that causes the movable layer 1142 to move by decreasing the stiffness of the movable layer 1142. In some implementations, in order to not affect the properties of an active region 1012, the features 1148 and 1150 in the movable layer 1142 may be within inactive regions 1010 of the EMS device 1140. The features 1148 and 1150 in the movable layer 1142 may have a similar configuration as the features 1108 and 1110 in the movable layer 1102 shown in FIG. 11B. For example, in some implementations, the features 1148 and 1150 in the movable layer 1142 substantially may form an arc associated with each of the anchor points 1144 and may have similar dimensions as the features 1108 and 1110.

The EMS device 1160 shown in FIG. 11D includes the substrate 902, layers 1002 and 1004 disposed on the substrate 902, and the movable layer 1162. In some implementations, the movable layer 1162 may be a movable reflective layer. The movable layer 1162 may contact and/or be attached to the layer 1004 disposed on the substrate 902 at anchor points 1164. In the cross-sectional schematic illustration shown in FIG. 11C, four features 1168 and 1170 are included in the movable layer 1162. The features 1168 may protrude out from the cavity 1016 defined by the movable layer 1162 and the layer 1004 disposed on the substrate 902. The features 1170 may protrude into the cavity 1016. In some implementations, dimensions 1172 and 1174 of the features 1168 and 1170, respectively, may be about 50 nm to 1 micron. In some implementations, an angle that a planar portion of the movable layer 1162 (i.e., a portion of the movable layer 1162 that may be substantially parallel to the surface of the substrate 902) makes with a sloped portion of the movable layer 1162 may be about 100 degrees to 150 degrees or about 120 degrees to 135 degrees.

The features 1168 and 1170 in the movable layer 1162 may decrease a force that causes the movable layer 1162 to move by decreasing the stiffness of the movable layer 1162. In some implementations, in order to not affect the properties of an active region 1012, the features 1168 and 1170 in the movable layer 1162 may be within inactive regions 1010 of the EMS device 1160. The features 1168 and 1170 in the movable layer 1162 may have a similar configuration as the features 1108 and 1110 in the movable layer 1102 shown in FIG. 11B. For example, in some implementations, the features 1168 and 1170 in the movable layer 1162 substantially may form an arc associated with each of the anchor points 1164 and may have similar dimensions as the features 1108 and 1110.

FIG. 11E shows an example of a top-down schematic illustration of an anchor point of a movable layer of an EMS device and two features associated with the anchor point. As shown in FIG. 11E, a portion of a movable layer 1180 may include an anchor point 1182 and features 1184 and 1186 associated with the anchor point 1182. In some implementations, the features 1184 and 1186 in the movable layer 1180 substantially may form the perimeters of one quarter of octagons that are approximately centered at a center of the anchor point 1182. The movable layer 1180 also overlies an active region 1012 and an inactive region 1010 of the EMS device. The inactive region 1010 corresponds to a quarter circle at a corner of the movable layer 1080. In the inactive region 1010 are the anchor point 1182 and the features 1184 and 1186. In some implementations, a dimension 1188 of the feature 1084 and a dimension 1190 of the feature 1186 (e.g., a width of the features 1184 and 1186) may be about 2 microns to 10 microns. In some implementations, the features 1184 and 1186 may be about 2 microns to 25 microns from a center point of the anchor point 1182, with the feature 1184 being closer to the anchor point 1182 than the feature 1186.

The features 1184 and 1186 in the movable layer 1180 may decrease a force that causes the movable layer 1180 to move by decreasing the stiffness of the movable layer 1180. Features similar to the features 1108 and 1110 shown in FIG. 11B or the features 1184 and 1186 shown in FIG. 11E may be formed in the movable layer of an EMS device. In some implementations, the features 1108 and 1110 shown in FIG. 11B (i.e., arc-shaped features) or the features 1184 and 1186 shown in FIG. 11E (i.e., octagon-shaped features) formed in the movable layer of an EMS device may aid in the symmetry of actuation of the EMS device.

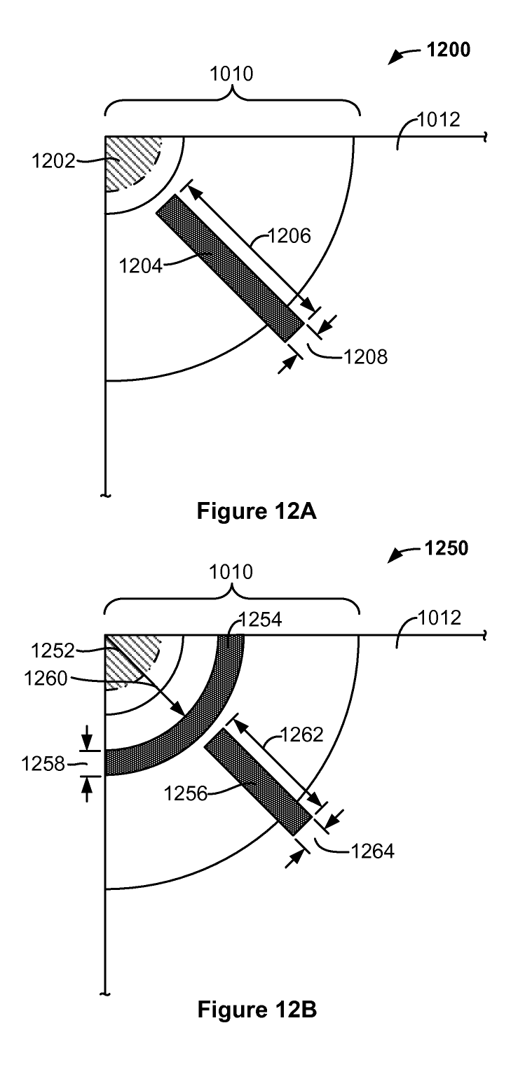

As noted above, the features in a movable layer shown in FIGS. 10A-10D and FIGS. 11A-11E may decrease the stiffness of the movable layer. Features in a movable layer also may increase the stiffness of a movable layer. FIGS. 12A and 12B show examples of top-down schematic illustrations of an anchor point of a movable layer and features associated with the anchor point. The feature shown in FIG. 12A may increase the stiffness of the movable layer. One of the features shown in FIG. 12B may decrease the stiffness of the movable layer, and one of the features shown in FIG. 12B may increase the stiffness of the movable layer. The implementation shown in FIG. 12B may be used to more precisely adjust or tune the stiffness of the movable layer. For example, various combinations of features (such as those shown in FIG. 12B) may be used in the movable layers of IMODs associated with different colors for tuning the stiffness of their movable layers, and hence, to control or adjust the respective actuation voltages of the IMODs.

As shown in FIG. 12A, a portion of a movable layer 1200 may include an anchor point 1202 and a feature 1204 associated with the anchor point 1202. In some implementations, the feature 1204 in the movable layer 1200 may extend substantially radially from the anchor point 1202 into an active region 1012. In some implementations, the feature 1204 may be removed from and not in contact with the anchor point 1202. The movable layer 1200 also may overlie the active region 1012 and an inactive region 1010 of the EMS device. The inactive region 1010 includes the one quarter of a circle in the movable layer 1200. In some implementations, the anchor point 1202 and the feature 1204 are in the inactive region 1010. In some implementations, the feature 1204 may extend slightly into the active region 1012, and in some implementations, the feature 1204 may be partially or wholly within the inactive region 1010. In some implementations, the feature 1204 may extend partially or fully across the active region 1012, but the feature 1204 extending across the active region 1012 may degrade the performance of the EMS device of which the movable layer 1200 is a component. In some implementations, a length 1206 of the feature 1204 may be about 2 microns to 25 microns. In some implementations, a width 1208 of the feature 1204 may be about 2 microns to 10 microns. In some implementations, the feature 1204 may protrude into or out from a cavity (not shown) defined by the movable layer 1200 and a substrate (not shown) of the EMS device of which the movable layer 1200 is a component. The feature 1204 may protrude into or out from the cavity by about 50 nm to 1 micron.

FIG. 12B shows an example of a top-down schematic illustration of an anchor point of a movable layer of an EMS device and two features associated with the anchor point. One of the features is similar to the feature 1204 described with respect to FIG. 12A, and one of the features is similar to the feature 1020 described with respect to FIGS. 10A and 10B. As shown in FIG. 12B, a portion of a movable layer 1250 may include an anchor point 1252 and features 1254 and 1256 associated with the anchor point 1252. The feature 1256 may increase the stiffness of the movable layer 1250, and the feature 1254 may decrease the stiffness of the movable layer 1250. The movable layer 1250 also may overlie an active region 1012 and an inactive region 1010 of the EMS device. In some implementations, in the inactive region 1010 are the anchor point 1252 and the features 1254 and 1256. The inactive region 1010 has a shape that approximates a quarter of a circle in the movable layer 1250 as shown in FIG. 12B. In some implementations, the feature 1254 in the movable layer 1250 may form an arc associated with the anchor point 1252. In some implementations, a dimension 1258 of the arc of the feature 1254 (e.g., a width of the feature 1254) may be about 2 microns to 10 microns. In some implementations, a radius 1260 of the arc of the feature 1254 may be about 2 microns to 25 microns.

In some implementations, the feature 1256 in the movable layer 1250 may extend substantially radially from the first anchor point 1252 towards the active region 1012. In some implementations, the feature 1256 may be further away from the anchor point 1252 than the feature 1254. In some implementations, the feature 1256 may extend slightly into the active region 1012, and in some implementations, the feature 1256 may be within the inactive region 1010. In some implementations, the feature 1256 may extend partially or fully across the active region 1012, but the feature 1256 extending across the active region 1012 may degrade the performance of the EMS device of which the movable layer 1250 is a component. In some implementations, a length 1262 of the feature 1256 may be about 2 microns to 25 microns. In some implementations, a width 1264 of the feature 1256 may be about 2 microns to 10 microns. In some implementations, the features 1254 and 1256 may protrude into or out from a cavity (not shown) defined by the movable layer 1250 and a substrate (not shown) of the EMS device of which the movable layer 1250 is a component. The features 1254 and 1256 may protrude into or out from the cavity by about 50 nm to 1 micron.

While the feature 1254 is closer to the anchor point 1252 than the feature 1256 as shown in FIG. 12B, in some other implementations, the feature 1256 may be closer to the anchor point 1252 than the feature 1254.

Further, while FIGS. 10A-10D, 11A-11E, 12A, and 12B show movable layers having one or two features associated with each anchor point of the movable layer, a movable layer may have additional features (e.g., three or more features) associated with an anchor point in the movable layer. Furthermore, the features may be of the same type or of different types, such as the various types of features discussed above.

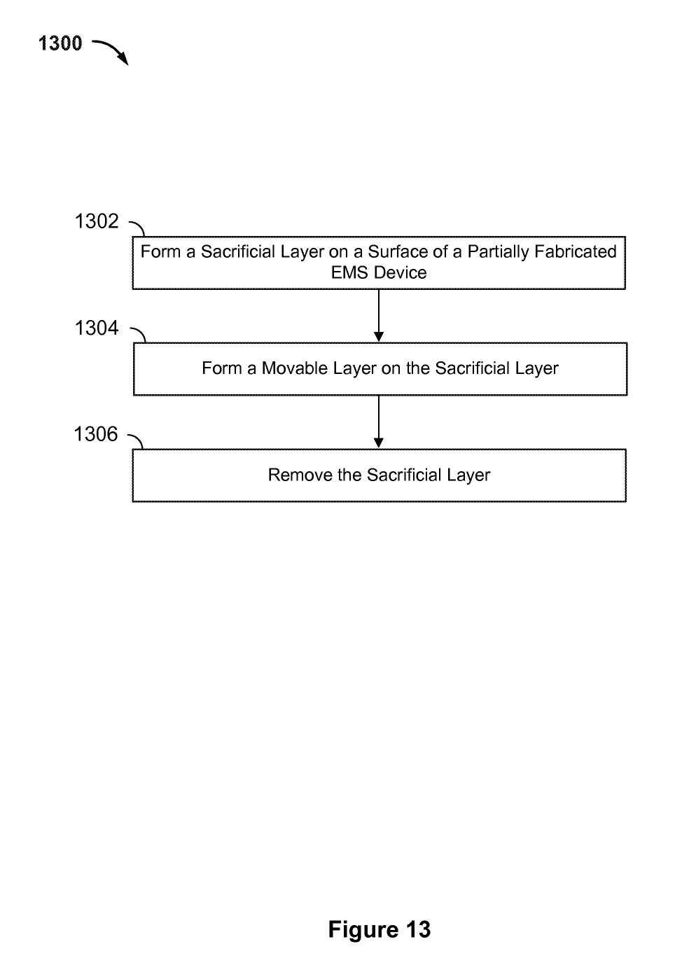

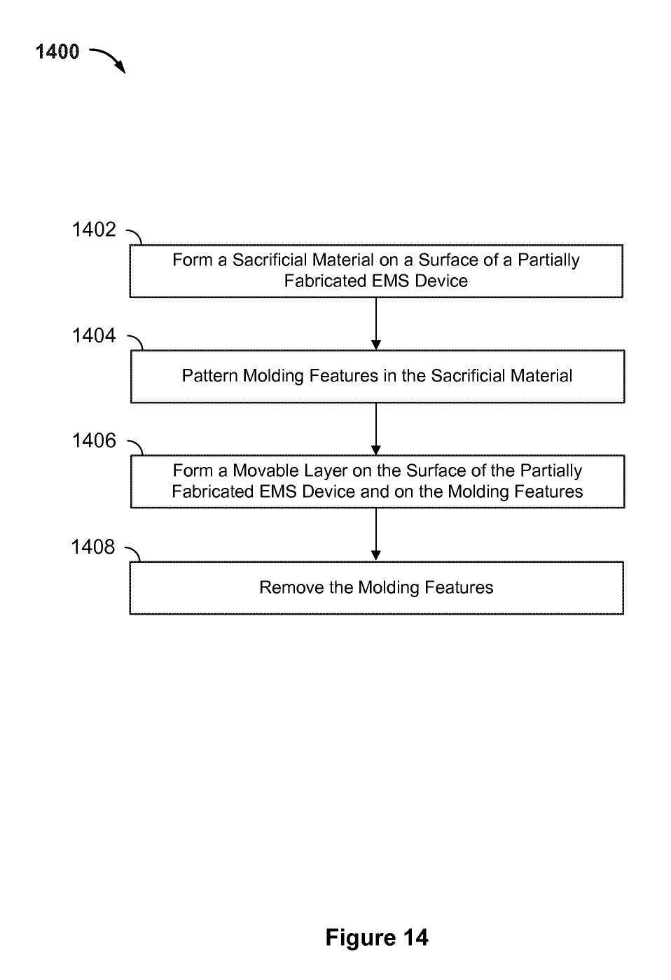

FIGS. 13 and 14 show examples of flow diagrams illustrating manufacturing processes for forming a movable layer of an EMS device. For example, in some implementations, the process 1300 shown in FIG. 13 and the process 1400 shown in FIG. 14 may be part of the process 80 and/or replace some of the operations in the process 80 shown in FIG. 7.

Turning first to FIG. 13, at block 1302 of the process 1300 a sacrificial layer is formed on a surface of a partially fabricated EMS device. The sacrificial layer may include a XeF₂-etchable material, such as Mo or amorphous Si, in a thickness selected to provide, after subsequent removal, a cavity having a desired size. The sacrificial layer may be formed using deposition processes, such as PVD processes and chemical vapor deposition (CVD) processes.

In some implementations, molding features may be formed in the sacrificial layer with a patterning process. These molding features may serve to create features in a movable layer to be formed. Masks, for example, may be used in the patterning process to form the molding features in the sacrificial layer. The molding features may have dimensions selected to provide features in the movable layer having a desired height, width, and shape.

In some other implementations, a patterning process to form molding features in the sacrificial layer may not be used. For example, in some implementations, molding features in the sacrificial layer may be formed by features in layers of the EMS device already formed on the substrate. For example, the substrate may have other layers and/or components of the EMS device formed on it before the sacrificial layer is formed. The sacrificial layer may be a conformal layer, such that the features in the EMS device layers are formed in the sacrificial layer as molding features. For example, for one implementation of an IMOD, features may be included in different layers (e.g., the black mask structure, oxide layers, or the color enhancement layer) of the optical stack that is formed on the substrate. When the sacrificial layer is formed on the optical stack, the features in the optical stack may be formed as molding features in the sacrificial layer. In some implementations, operations performed in block 1302 of the process 1300 may be similar to operations performed in block 84 of the process 80 shown in FIG. 7.

At block 1304, a movable layer is formed on the sacrificial layer. The molding features in the sacrificial layer may form features in the movable layer. The layer or layers of the movable layer formed will depend on the design of the EMS device being fabricated. For example, for an IMOD, the movable layer may be a movable reflective layer including a conductive layer, a support layer, and a reflective sub-layer. In some implementations, operations performed in block 1304 of the process 1300 may be similar to operations performed in block 88 of the process 80 shown in FIG. 7. For example, the movable layer may be formed by employing one or more deposition processes, such as PVD processes, CVD processes, and atomic layer deposition (ALD) processes.

At block 1306, the sacrificial layer is removed. When the sacrificial layer is Mo or amorphous Si, XeF₂ may be used to remove the sacrificial layer by exposing the sacrificial layer to XeF₂. Removal of the sacrificial layer may form a cavity between the movable layer and the substrate. Further, due to the molding features present in the sacrificial layer, features conforming to the shapes and sizes of the molding features are formed in the movable layer. Such features in the movable layer may increase the stiffness or to decrease the stiffness of the movable layer. In some implementations, operations performed in block 1306 of the process 1300 may be similar to operations performed in block 90 of the process 80 shown in FIG. 7.

Turning next to FIG. 14, FIG. 14 shows another example of a flow diagram illustrating a manufacturing process for forming a movable layer of an EMS device. FIGS. 15A-15C show examples of cross-sectional schematic illustrations of an EMS device in various stages of the manufacturing process shown in FIG. 14. The EMS device shown in FIGS. 15A-15C may be an IMOD, which may be similar to the IMOD shown in FIG. 6C, in some implementations. The movable layer of the EMS device shown in FIGS. 15B and 15C also may be referred to as a deformable layer.

At block 1402 of the process 1400 in FIG. 14, a sacrificial material is formed on a surface of a partially fabricated EMS device. The sacrificial material may include a XeF₂-etchable material such as Mo or amorphous Si. The sacrificial material may be formed using deposition processes, such as PVD processes and CVD processes.

At block 1404, the sacrificial material is patterned to form molding features therein. The molding features may have dimensions selected to provide, after subsequent removal, features in the movable layer having a desired height, width, and shape.

FIG. 15A shows an example of a cross-sectional schematic illustration of an EMS device 1500 at this point (e.g., up through block 1404) in the process 1400. In some implementations, the EMS device 1500 may be similar to the example of an IMOD including the movable reflective layer 14 and the deformable layer 34 shown in FIG. 6C. The EMS device 1500 includes a substrate 902 having an optical stack 1504 on a surface of the substrate 902. The optical stack may include a partially reflective layer. A sacrificial layer 1506 provides a surface and/or surfaces on which the movable reflective layer 1508 and support posts 1510 have been formed. For example, in previous operations in the manufacturing process for the EMS device 1500, a portion of the sacrificial layer 1506 may be formed, the movable reflective layer 1508 may be formed on the portion of the sacrificial layer 1506, and then the remainder of the sacrificial layer 1506 may be formed over the movable reflective layer 1508. Molding features 1512 are structures patterned in the sacrificial material formed in block 1402. In some implementations, the molding features 1512 may be made of the same material as the sacrificial layer 1506. In some other implementations, the molding features 1512 may be made out of a different material than the sacrificial layer 1506.

Returning FIG. 14, at block 1406 a movable layer is formed on the surfaces of the partially fabricated EMS device and on the molding features. The movable layer also may be formed on a portion of the movable reflective layer such that a connection is formed between the movable layer and the movable reflective layer. In some implementations, the movable layer may include a flexible metal. In some implementations, the movable layer may be formed by employing one or more deposition processes, such as PVD processes, CVD processes, and ALD processes.

FIG. 15B shows an example of a cross-sectional schematic illustration of the EMS device 1500 at this point (e.g., up through block 1406) in the process 1400. A movable layer 1522 is disposed on the surfaces (e.g., the support posts 1510) of the partially fabricated EMS device and on the molding features 1512 of the sacrificial material. The movable layer 1522 is also disposed on a portion of the movable reflective layer 1508, forming a connector 1524 between the movable layer 1522 and the movable reflective layer 1508.

Returning to FIG. 14, at block 1408 the molding features are removed. When the sacrificial material used to form the molding features is Mo or amorphous Si, XeF₂ may be used to remove the molding features by exposing the molding features to XeF₂. Further, removing the molding features used to form features in the movable layer of an EMS device also may remove other sacrificial layers and/or sacrificial materials used in the fabrication of the EMS device. For example, with reference to the EMS device 1500 shown in FIG. 15B, removing the molding features 1512 also may be performed at the same time the sacrificial layer 1506 is removed.

FIG. 15C shows an example of a cross-sectional schematic illustration of the EMS device 1500 at this point (e.g., up through block 1408) in the process 1400. The EMS device 1500 includes a substrate 1502 having an optical stack 1504 on a surface of the substrate 1502. The optical stack 1504 may include a partially reflective layer. The support posts 1510 support the movable layer 1522, which in turn supports the movable reflective layer 1508 by the connector 1524. The movable reflective layer 1508 may be suspended in the cavity 1528 formed by the removal of the sacrificial layer. The movable layer 1522 includes features 1526 formed by the removal of the molding features. The features 1526 may reduce the stiffness of the movable layer 1522.

In the EMS devices described above with respect to FIGS. 10A-10C and 11A-11D, the properties of the movable layer, including the mechanical properties of the movable layer, may allow the EMS devices to operate. The movable layer described in these figures (i.e., FIGS. 10A-10C and 11A-11D) may be a layer or layers of material having similar properties (e.g., mechanical properties and optical properties) throughout the movable layer, with the movable layer overlying active regions and inactive regions of the EMS device.

In some other EMS devices, the movable layer may have certain mechanical properties, and the movable layer may provide for movement of other components of the EMS device into or out of a cavity of the EMS device. In these implementations, other properties, such as optical properties, for example, of the movable layer may not be important. The other components associated with the movable layer may include components that allow for the operation of the EMS device. The EMS device 1500 as described in FIGS. 15A-15C is an example of an EMS device in which the movable layer 1522 may provide for movement of the movable reflective layer 1508. As described above with reference to the example of an IMOD shown in FIG. 6C, optical functions of the movable reflective layer 14 can be decoupled from its mechanical functions, with the mechanical functions being performed by the deformable layer 34. In a similar manner, the EMS device 1500 shown in FIG. 15C may benefit from the decoupling of the optical functions of the movable reflective layer 1508 from its mechanical properties. The actuation voltages of the EMS device 1500 may be determined by the movable layer 1522.

FIGS. 10A-10C, 11A-11D, and 15C show examples of cross-sectional schematic illustrations of EMS devices that include a substrate and a movable layer, with a cavity being defined by the substrate and the movable layer or structures associated with the movable layer. In some other implementations, cavities in an EMS device may be defined by other layers of an EMS device. For example, in some implementations, an EMS device may include a substrate, a movable layer, and second layer. The movable layer may be located between the substrate and the second layer. The movable layer and the substrate may define a first cavity. The second layer and the movable layer may define a second cavity. In some implementations, such an EMS device may operate by the motion of the movable layer into and out of the first cavity and the second cavity. In some implementations, the movable layer or a component associated with the movable layer of such an EMS device may come into and out of contact with the substrate and/or the second layer.

While the movable layers described herein may have a substantially square shape, a movable layer may have any number of different shapes. For example, the movable layer may be in the shape of a square, a rectangle, a triangle, an octagon, a circle, an oval, etc. Dimensions of the movable layer may be about 5 microns to 1 mm, in some implementations. Further, while the movable layers describe herein have four anchor points associated with the movable layer, fewer or more anchor points may be associated with the movable layer. For example, when the movable layer is triangular, there may be three anchor points associated with the movable layer.

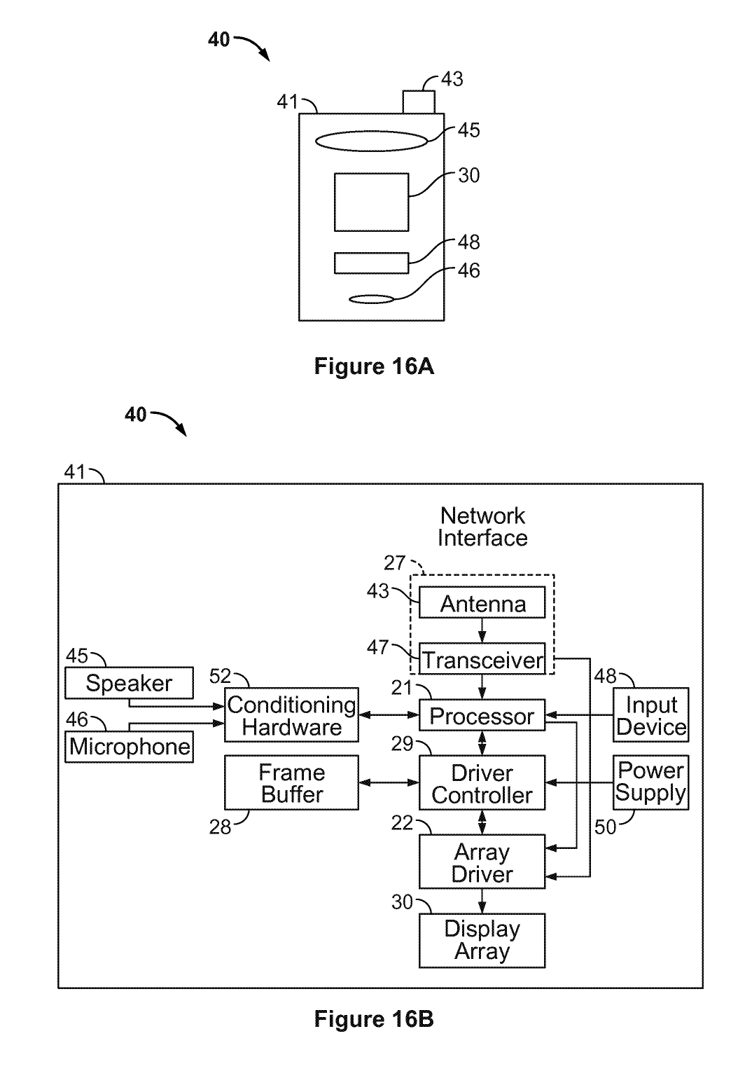

FIGS. 16A and 16B show examples of system block diagrams illustrating a display device 40 that includes a plurality of interferometric modulators. The display device 40 can be, for example, a smart phone, a cellular or mobile telephone. However, the same components of the display device 40 or slight variations thereof are also illustrative of various types of display devices such as televisions, tablets, e-readers, hand-held devices and portable media players.

The display device 40 includes a housing 41, a display 30, an antenna 43, a speaker 45, an input device 48 and a microphone 46. The housing 41 can be formed from any of a variety of manufacturing processes, including injection molding, and vacuum forming. In addition, the housing 41 may be made from any of a variety of materials, including, but not limited to: plastic, metal, glass, rubber and ceramic, or a combination thereof. The housing 41 can include removable portions (not shown) that may be interchanged with other removable portions of different color, or containing different logos, pictures, or symbols.

The display 30 may be any of a variety of displays, including a bi-stable or analog display, as described herein. The display 30 also can be configured to include a flat-panel display, such as plasma, EL, OLED, STN LCD, or TFT LCD, or a non-flat-panel display, such as a CRT or other tube device. In addition, the display 30 can include an interferometric modulator display, as described herein.

The components of the display device 40 are schematically illustrated in FIG. 16B. The display device 40 includes a housing 41 and can include additional components at least partially enclosed therein. For example, the display device 40 includes a network interface 27 that includes an antenna 43 which is coupled to a transceiver 47. The transceiver 47 is connected to a processor 21, which is connected to conditioning hardware 52. The conditioning hardware 52 may be configured to condition a signal (e.g., filter a signal). The conditioning hardware 52 is connected to a speaker 45 and a microphone 46. The processor 21 is also connected to an input device 48 and a driver controller 29. The driver controller 29 is coupled to a frame buffer 28, and to an array driver 22, which in turn is coupled to a display array 30. In some implementations, a power supply 50 can provide power to substantially all components in the particular display device 40 design.

The network interface 27 includes the antenna 43 and the transceiver 47 so that the display device 40 can communicate with one or more devices over a network. The network interface 27 also may have some processing capabilities to relieve, for example, data processing requirements of the processor 21. The antenna 43 can transmit and receive signals. In some implementations, the antenna 43 transmits and receives RF signals according to the IEEE 16.11 standard, including IEEE 16.11(a), (b), or (g), or the IEEE 802.11 standard, including IEEE 802.11a, b, g, n, and further implementations thereof. In some other implementations, the antenna 43 transmits and receives RF signals according to the BLUETOOTH standard. In the case of a cellular telephone, the antenna 43 is designed to receive code division multiple access (CDMA), frequency division multiple access (FDMA), time division multiple access (TDMA), Global System for Mobile communications (GSM), GSM/General Packet Radio Service (GPRS), Enhanced Data GSM Environment (EDGE), Terrestrial Trunked Radio (TETRA), Wideband-CDMA (W-CDMA), Evolution Data Optimized (EV-DO), 1xEV-DO, EV-DO Rev A, EV-DO Rev B, High Speed Packet Access (HSPA), High Speed Downlink Packet Access (HSDPA), High Speed Uplink Packet Access (HSUPA), Evolved High Speed Packet Access (HSPA+), Long Term Evolution (LTE), AMPS, or other known signals that are used to communicate within a wireless network, such as a system utilizing 3G or 4G technology. The transceiver 47 can pre-process the signals received from the antenna 43 so that they may be received by and further manipulated by the processor 21. The transceiver 47 also can process signals received from the processor 21 so that they may be transmitted from the display device 40 via the antenna 43.

In some implementations, the transceiver 47 can be replaced by a receiver. In addition, in some implementations, the network interface 27 can be replaced by an image source, which can store or generate image data to be sent to the processor 21. The processor 21 can control the overall operation of the display device 40. The processor 21 receives data, such as compressed image data from the network interface 27 or an image source, and processes the data into raw image data or into a format that is readily processed into raw image data. The processor 21 can send the processed data to the driver controller 29 or to the frame buffer 28 for storage. Raw data typically refers to the information that identifies the image characteristics at each location within an image. For example, such image characteristics can include color, saturation and gray-scale level.

The processor 21 can include a microcontroller, CPU, or logic unit to control operation of the display device 40. The conditioning hardware 52 may include amplifiers and filters for transmitting signals to the speaker 45, and for receiving signals from the microphone 46. The conditioning hardware 52 may be discrete components within the display device 40, or may be incorporated within the processor 21 or other components.

The driver controller 29 can take the raw image data generated by the processor 21 either directly from the processor 21 or from the frame buffer 28 and can re-format the raw image data appropriately for high speed transmission to the array driver 22. In some implementations, the driver controller 29 can re-format the raw image data into a data flow having a raster-like format, such that it has a time order suitable for scanning across the display array 30. Then the driver controller 29 sends the formatted information to the array driver 22. Although a driver controller 29, such as an LCD controller, is often associated with the system processor 21 as a stand-alone Integrated Circuit (IC), such controllers may be implemented in many ways. For example, controllers may be embedded in the processor 21 as hardware, embedded in the processor 21 as software, or fully integrated in hardware with the array driver 22.

The array driver 22 can receive the formatted information from the driver controller 29 and can re-format the video data into a parallel set of waveforms that are applied many times per second to the hundreds, and sometimes thousands (or more), of leads coming from the display's x-y matrix of pixels.

In some implementations, the driver controller 29, the array driver 22, and the display array 30 are appropriate for any of the types of displays described herein. For example, the driver controller 29 can be a conventional display controller or a bi-stable display controller (such as an IMOD controller). Additionally, the array driver 22 can be a conventional driver or a bi-stable display driver (such as an IMOD display driver). Moreover, the display array 30 can be a conventional display array or a bi-stable display array (such as a display including an array of IMODs). In some implementations, the driver controller 29 can be integrated with the array driver 22. Such an implementation can be useful in highly integrated systems, for example, mobile phones, portable-electronic devices, watches or small-area displays.

In some implementations, the input device 48 can be configured to allow, for example, a user to control the operation of the display device 40. The input device 48 can include a keypad, such as a QWERTY keyboard or a telephone keypad, a button, a switch, a rocker, a touch-sensitive screen, a touch-sensitive screen integrated with display array 30, or a pressure- or heat-sensitive membrane. The microphone 46 can be configured as an input device for the display device 40. In some implementations, voice commands through the microphone 46 can be used for controlling operations of the display device 40.

The power supply 50 can include a variety of energy storage devices. For example, the power supply 50 can be a rechargeable battery, such as a nickel-cadmium battery or a lithium-ion battery. In implementations using a rechargeable battery, the rechargeable battery may be chargeable using power coming from, for example, a wall socket or a photovoltaic device or array. Alternatively, the rechargeable battery can be wirelessly chargeable. The power supply 50 also can be a renewable energy source, a capacitor, or a solar cell, including a plastic solar cell or solar-cell paint. The power supply 50 also can be configured to receive power from a wall outlet.

In some implementations, control programmability resides in the driver controller 29 which can be located in several places in the electronic display system. In some other implementations, control programmability resides in the array driver 22. The above-described optimization may be implemented in any number of hardware and/or software components and in various configurations.

The various illustrative logics, logical blocks, modules, circuits and algorithm steps described in connection with the implementations disclosed herein may be implemented as electronic hardware, computer software, or combinations of both. The interchangeability of hardware and software has been described generally, in terms of functionality, and illustrated in the various illustrative components, blocks, modules, circuits and steps described above. Whether such functionality is implemented in hardware or software depends upon the particular application and design constraints imposed on the overall system.

The hardware and data processing apparatus used to implement the various illustrative logics, logical blocks, modules and circuits described in connection with the aspects disclosed herein may be implemented or performed with a general purpose single- or multi-chip processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general purpose processor may be a microprocessor, or, any conventional processor, controller, microcontroller, or state machine. A processor also may be implemented as a combination of computing devices, such as a combination of a DSP and a microprocessor, a plurality of microprocessors, one or more microprocessors in conjunction with a DSP core, or any other such configuration. In some implementations, particular steps and methods may be performed by circuitry that is specific to a given function.

In one or more aspects, the functions described may be implemented in hardware, digital electronic circuitry, computer software, firmware, including the structures disclosed in this specification and their structural equivalents thereof, or in any combination thereof. Implementations of the subject matter described in this specification also can be implemented as one or more computer programs, i.e., one or more modules of computer program instructions, encoded on a computer storage media for execution by, or to control the operation of, data processing apparatus.

Various modifications to the implementations described in this disclosure may be readily apparent to those skilled in the art, and the generic principles defined herein may be applied to other implementations without departing from the spirit or scope of this disclosure. Thus, the claims are not intended to be limited to the implementations shown herein, but are to be accorded the widest scope consistent with this disclosure, the principles and the novel features disclosed herein. The word “exemplary” is used exclusively herein to mean “serving as an example, instance, or illustration.” Any implementation described herein as “exemplary” is not necessarily to be construed as preferred or advantageous over other possibilities or implementations. Additionally, a person having ordinary skill in the art will readily appreciate, the terms “upper” and “lower” are sometimes used for ease of describing the figures, and indicate relative positions corresponding to the orientation of the figure on a properly oriented page, and may not reflect the proper orientation of an IMOD as implemented.

Certain features that are described in this specification in the context of separate implementations also can be implemented in combination in a single implementation. Conversely, various features that are described in the context of a single implementation also can be implemented in multiple implementations separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, a person having ordinary skill in the art will readily recognize that such operations need not be performed in the particular order shown or in sequential order, or that all illustrated operations be performed, to achieve desirable results. Further, the drawings may schematically depict one more example processes in the form of a flow diagram. However, other operations that are not depicted can be incorporated in the example processes that are schematically illustrated. For example, one or more additional operations can be performed before, after, simultaneously, or between any of the illustrated operations. In certain circumstances, multitasking and parallel processing may be advantageous. Moreover, the separation of various system components in the implementations described above should not be understood as requiring such separation in all implementations, and it should be understood that the described program components and systems can generally be integrated together in a single software product or packaged into multiple software products. Additionally, other implementations are within the scope of the following claims. In some cases, the actions recited in the claims can be performed in a different order and still achieve desirable results.

What is claimed is:

1. A device comprising:
a substrate; and
a movable layer positioned apart from the substrate, the movable layer and the substrate defining a cavity, the movable layer being movable to increase the size of the cavity or to decrease the size of the cavity, the movable layer including:
a first anchor point attaching the movable layer to the substrate, and
a first feature associated with the first anchor point, the first feature including a protrusion of the movable layer into or out from the cavity.

2. The device of claim 1, wherein the first feature extends substantially radially from the first anchor point.

3. The device of claim 2, wherein the first feature increases a force that causes the movable layer to move.

4. The device of claim 1, wherein the first feature extends substantially radially from the first anchor point by about 2 microns to 25 microns.

5. The device of claim 1, wherein the first feature substantially forms an arc associated with the first anchor point.

6. The device of claim 5, wherein the first feature decreases a force that causes the movable layer to move.

7. The device of claim 5, wherein a radius of the arc substantially formed by the first feature is about 2 microns to 25 microns.

8. The device of claim 1, wherein a width of the first feature is about 2 microns to 10 microns.

9. The device of claim 1, wherein the first feature protrudes into or out from the cavity by about 50 nanometers to 1 micron.

10. The device of claim 1, wherein the movable layer further includes:
a second feature associated with the first anchor point, the second feature including a protrusion of the movable layer into or out from the cavity.

11. The device of claim 10, wherein the first feature decreases a force that causes the movable layer to move, and wherein the second feature increases a force that causes the movable layer to move.

12. The device of claim 1, wherein an angle that a planar region of the movable layer makes with a side of the first feature is about 100 degrees to 150 degrees.

13. The device to claim 1, the movable layer further including:
a second anchor point attaching the movable layer to the substrate;
a second feature associated with the second anchor point, the second feature including a protrusion of the movable layer into or out from the cavity;
a third anchor point attaching the movable layer to the substrate; and
a third feature associated with the third anchor point, the third feature including a protrusion of the movable layer into or out from the cavity.

14. The device of claim 1, wherein the device includes an electromechanical systems reflective display device, wherein the substrate and the movable layer form an optically active region of the display device and an optically inactive region of the display device, and wherein the first anchor point is in the optically inactive region of the device.

15. The device of claim 14, wherein the first feature is in the optically inactive region of the device.

16. A system comprising the device of claim 1, the system further comprising:
a display;
a processor that is configured to communicate with the display, the processor being configured to process image data; and
a memory device that is configured to communicate with the processor.

17. The system of claim 16, further comprising:
a driver circuit configured to send at least one signal to the display; and
a controller configured to send at least a portion of the image data to the driver circuit.

18. The system of claim 16, further comprising:
an image source module configured to send the image data to the processor.

19. The system of claim 18, wherein the image source module includes at least one of a receiver, transceiver, and transmitter.

20. The system of claim 16, further comprising:
an input device configured to receive input data and to communicate the input data to the processor.

21. An electromechanical systems reflective display device comprising:
a substrate; and
a movable layer positioned apart from the substrate, the movable layer and the substrate defining a cavity, the movable layer being movable into or out from the cavity, the substrate and the movable layer forming an optically active region configured to transmit and reflect light and an optically inactive region configured to absorb light, the movable layer including a first feature in the optically inactive region of the movable layer, the first feature including a protrusion of the movable layer into or out from the cavity.

22. The electromechanical systems reflective display device of claim 21, wherein the first feature extends substantially radially from a first anchor point within the optically inactive region, and wherein the first anchor point attaches the movable layer to the substrate.

23. The electromechanical systems reflective display device of claim 21, wherein the first feature substantially forms an arc associated with a first anchor point within the optically inactive region, and wherein the first anchor point attaches the movable layer to the substrate.

24. A device comprising:
a substrate; and
a movable layer positioned apart from the substrate, the movable layer and the substrate defining a cavity, the movable layer being movable to increase the size of the cavity or to decrease the size of the cavity, the movable layer including means for increasing or decreasing a force that causes the movable layer to move; and
means for attaching the movable layer to the substrate.

25. The device of claim 24, wherein the means for increasing or decreasing the force that causes the movable layer to move includes a first feature associated with the means for attaching the movable layer to the substrate.

26. The device of claim 24, wherein the means for attaching the movable layer to the substrate includes a first anchor point.

27. A method comprising:
forming a sacrificial layer over a substrate, the sacrificial layer including a molding feature;
forming a movable layer over the sacrificial layer, the movable layer including:
a first anchor point attaching the movable layer to the substrate, and
a first feature formed by the molding feature in the sacrificial layer, the first feature associated with the first anchor point: and
removing the sacrificial layer to form a cavity in between the movable layer and the substrate, the first feature including a protrusion of the movable layer into or out from the cavity.

28. The method of claim 27, wherein the sacrificial layer includes at least one of amorphous silicon and molybdenum.
